(19) United States
(12) Patent Application Publication
(10) Pub. No.: US 2025/0174477 A1
(43) Pub. Date: May 29, 2025

(54) SUBSTRATE TRANSFER APPARATUS AND SUBSTRATE PROCESSING APPARATUS INCLUDING THE SAME

(71) Applicant: SCREEN Holdings Co., Ltd., Kyoto (JP)

(72) Inventors: Hiroyuki KAWAHARA, Kyoto (JP); Yuichi TAKAYAMA, Kyoto (JP); Takuya SATO, Kyoto (JP)

(21) Appl. No.: 18/961,871

(22) Filed: Nov. 27, 2024

(30) Foreign Application Priority Data
Nov. 29, 2023 (JP) 2023-202090

(51) Int. Cl. H01L 21/677; H01L 21/683; H01L 21/687

(52) U.S. Cl. CPC H01L 21/67742; H01L 21/6835; H01L 21/68707; H01L 2221/68368

(57) ABSTRACT

A substrate transfer apparatus includes a hand, a horizontal drive mechanism that advances and retracts the hand, at least two guides that clamp an outer peripheral surface of the substrate to separate and hold the substrate from the hand, an advancing/retracting drive mechanism that drives at least one of the at least two guides, an acquisition unit that acquires clamp position information indicating a position in the horizontal plane where the guide clamps the outer peripheral surface of the substrate, and a control unit that determines a consumption degree of the guide on a basis of the acquired clamp position information.

### BACKGROUND OF THE INVENTION

### (1) Field of the Invention

The present invention relates to a substrate transfer apparatus that transfers a substrate such as a semiconductor substrate, a substrate for a flat panel display (FPD) such as a liquid crystal display or an organic electroluminescence (EL) display device, a glass substrate for a photomask, or a substrate for an optical disk, and a substrate processing apparatus including the substrate transfer apparatus.

### (2) Description of the Related Art

Conventionally, as this type of apparatus, there is an apparatus including a substrate transfer apparatus that transfers a substrate and a processing unit that processes the substrate. The substrate transfer apparatus includes a hand that grips a substrate. The hand includes a fixed guide that is fixed to a distal end side, and a movable guide that is provided on a proximal end side and movable forward and backward by a drive mechanism. The hand grips the substrate when the movable guide presses the substrate against the fixed guide while the substrate is supported by the fixed guide. For example, Japanese Patent Application Laid-Open No. 2021-48359 is referred to.

However, the conventional example having such a configuration has the following problems.

That is, in the conventional device, the fixed guide and the movable guide are worn by the hand repeatedly gripping the substrate. The worn state of the fixed guide and the movable guide is visually determined by the operator. Therefore, if the worn state is not appropriately determined, a transfer failure in which the substrate cannot be appropriately transferred may occur. As a result, there is a problem that the substrate cannot be efficiently transferred.

### SUMMARY OF THE INVENTION

The present invention has been made in view of such circumstances, and an object of the present invention is to provide a substrate transfer apparatus capable of efficiently transferring a substrate and a substrate processing apparatus including the same.

In order to achieve such an object, the present invention has the following configuration.

That is, the present invention provides a substrate transfer apparatus that transfers a substrate, the apparatus including: a hand that holds the substrate in a horizontal posture; a horizontal drive mechanism that advances and retracts the hand in a horizontal plane in order to deliver the substrate; at least two guides that are provided on the hand and clamp an outer peripheral surface of the substrate to separate and hold the substrate from the hand; an advancing/retracting drive mechanism that drives at least one of the at least two guides to advance and retract with respect to the substrate as a movable guide; an acquisition unit that acquires clamp position information indicating a position in the horizontal plane where the guide clamps the outer peripheral surface of the substrate; and a control unit that determines a consumption degree of the guide on a basis of the acquired clamp position information.

According to the present invention, the clamp position information indicating the position in the horizontal plane where the guide clamps the outer peripheral surface of the substrate is acquired, and the consumption degree of the guide is determined on the basis of the acquired clamp position information. The clamp position information changes depending on the consumption degree of the guide. By determining the consumption degree of the guide, transfer failure of the substrate can be made less likely to occur. As a result, it is possible to provide a substrate transfer apparatus capable of efficiently transferring a substrate.

Further, in the present invention, it is preferable that the control unit is configured to calculate differential information between the clamp position information of the guide in an initial state and the acquired clamp position information of the guide, and determine the consumption degree on a basis of the differential information. As a result, the consumption degree of the guide can be accurately detected by comparing the clamp position information of the guide in the initial state with the acquired clamp position information of the guide.

Further, in the present invention, it is preferable that the control unit performs first control in a case where the differential information exceeds a first threshold. As a result, in a case where the consumption degree of the guide is such that the differential information exceeds the first threshold, appropriate control can be performed.

Further, in the present invention, it is preferable that the control unit performs second control in a case where the differential information exceeds a second threshold having the consumption degree larger than the first threshold. As a result, in a case where a large consumption degree of the guide is such that the differential information exceeds the second threshold, more appropriate control can be performed.

Further, in the present invention, it is preferable that the advancing/retracting drive mechanism includes: a motor that applies a driving force for the advancing/retracting drive; and a sensor that detects rotation of the motor and outputs the rotation as a detection signal, and the acquisition unit acquires the clamp position information on a basis of the detection signal given by the sensor. As a result, the consumption degree can be suitably determined using the output from the sensor that detects the rotation of the motor.

Further, in the present invention, it is preferable that the advancing/retracting drive mechanism includes a measurement unit that measures a movement distance of the guide and outputs the movement distance as a measurement signal, and The acquisition unit acquires the clamp position information on a basis of the measurement signal given by the measurement unit. As a result, the consumption degree can be suitably determined using the output from the measurement unit that measures the movement distance of the guide.

Furthermore, in the present invention, it is preferable that the control unit causes an output unit that outputs information according to the consumption degree to output information according to the consumption degree. As a result, the operator can recognize the consumption degree of the guide.

Further, in the present invention, it is preferable that the control unit stops transfer of the substrate according to the consumption degree. As a result, transfer failure of the substrate can be prevented in advance.

Further, in the present invention, it is preferable that the control unit operates the guide such that a contact position between the guide and the outer peripheral surface of the substrate changes according to the consumption degree. As a result, the service life of the guide can be extended as compared with a case where the contact position is not changed.

The present invention relates to a substrate processing apparatus including: a substrate transfer apparatus that transfers a substrate; and a processing unit that performs predetermined processing on the substrate transferred by the substrate transfer apparatus. The substrate transfer apparatus includes: a hand that holds the substrate in a horizontal posture; a horizontal drive mechanism that advances and retracts the hand in a horizontal plane in order to deliver the substrate; at least two guides that are provided on the hand and clamp an outer peripheral surface of the substrate to separate and hold the substrate from the hand; an advancing/retracting drive mechanism that drives at least one of the at least two guides to advance and retract with respect to the substrate as a movable guide; an acquisition unit that acquires clamp position information indicating a position in the horizontal plane where the guide clamps the outer peripheral surface of the substrate; and a control unit that determines a consumption degree of the guide on a basis of the acquired clamp position information. As a result, it is possible to provide a substrate processing apparatus capable of efficiently processing a substrate as a result of efficiently transferring the substrate.

Further, in the present invention, it is preferable that the substrate clamped by the guide when the clamp position information is acquired is a substrate to be processed by the processing unit. As a result, the substrate processing apparatus can determine the consumption degree of the guide while operating normally.

Further, in the present invention, it is preferable that the substrate clamped by the guide when the clamp position information is acquired is a dummy substrate that is not processed by the processing unit. As a result, the substrate processing apparatus can determine the consumption degree of the guide without being affected by the difference in the shape of the substrate.

Further, in the present invention, it is preferable that the dummy substrate is placed in the substrate processing apparatus in advance, and the consumption degree is determined at a preset cycle. As a result, the consumption degree of the guide can be determined periodically in the substrate processing apparatus.

Further, in the present invention, it is preferable that the substrate processing apparatus includes a carrier placement part on which a carrier capable of housing a plurality of substrates is placed. The substrate transfer apparatus is a transfer robot that transfers a substrate placed in the carrier. As a result, the substrate processing apparatus can determine the consumption degree of the guide of the transfer robot that transfers the substrate placed in the carrier.

Further, in the present invention, it is preferable that the substrate processing apparatus includes: a carrier placement part on which a carrier capable of housing a plurality of substrates is placed; and a temporary placement part on which a substrate transferred from the carrier is temporarily placed. The substrate transfer apparatus is a transfer robot that transfers the substrate placed in the temporary placement part to the processing unit. As a result, the substrate processing apparatus can determine the consumption degree of the guide of the transfer robot that transfers the substrate placed in the temporary placement part to the processing unit.

BRIEF DESCRIPTION OF THE DRAWINGS
※ For the purpose of illustrating the invention, there
are shown in the drawings several forms which are
presently preferred, it being understood, however, that
the invention is not limited to the precise arrangement
and instrumentalities shown.

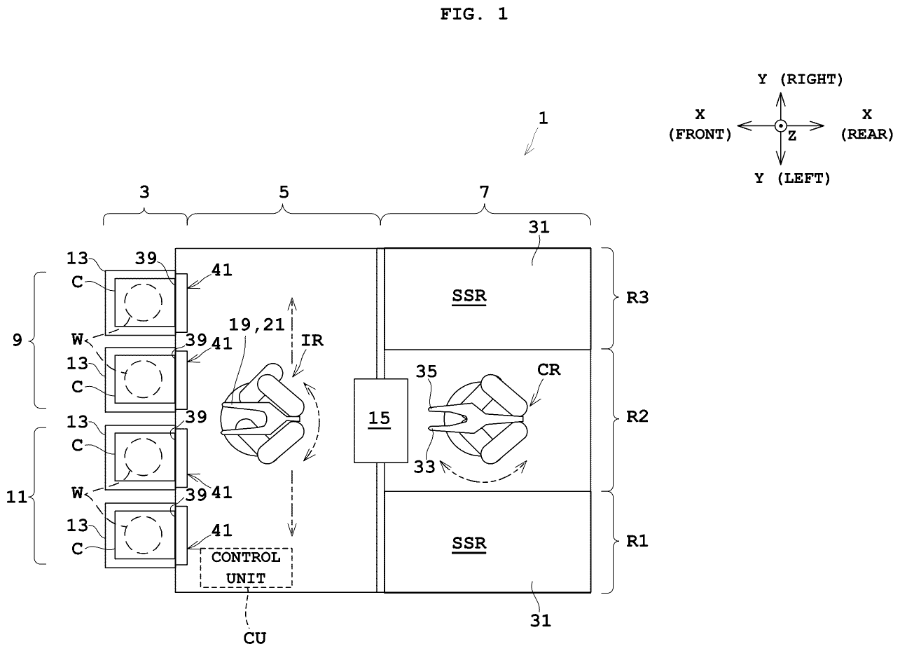

FIG. 1 is a plan view illustrating a schematic configuration of a substrate processing apparatus according to a first embodiment;

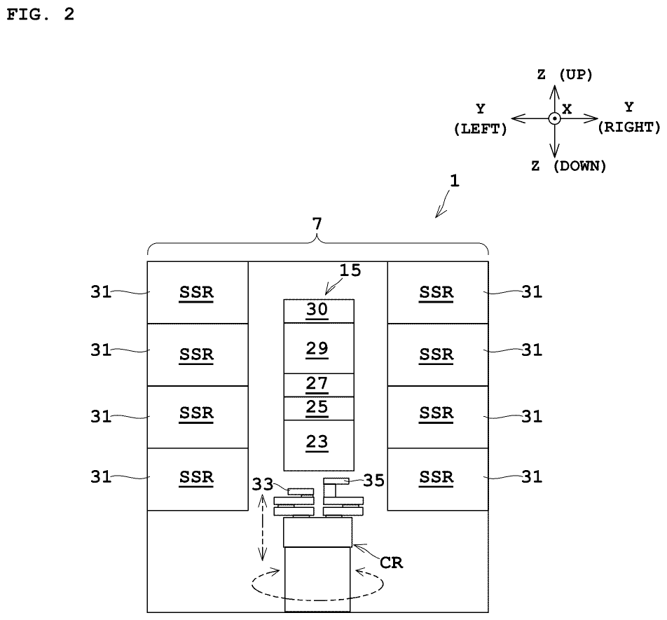

FIG. 2 is a view of the substrate processing apparatus of FIG. 1 as viewed from a rear side X;

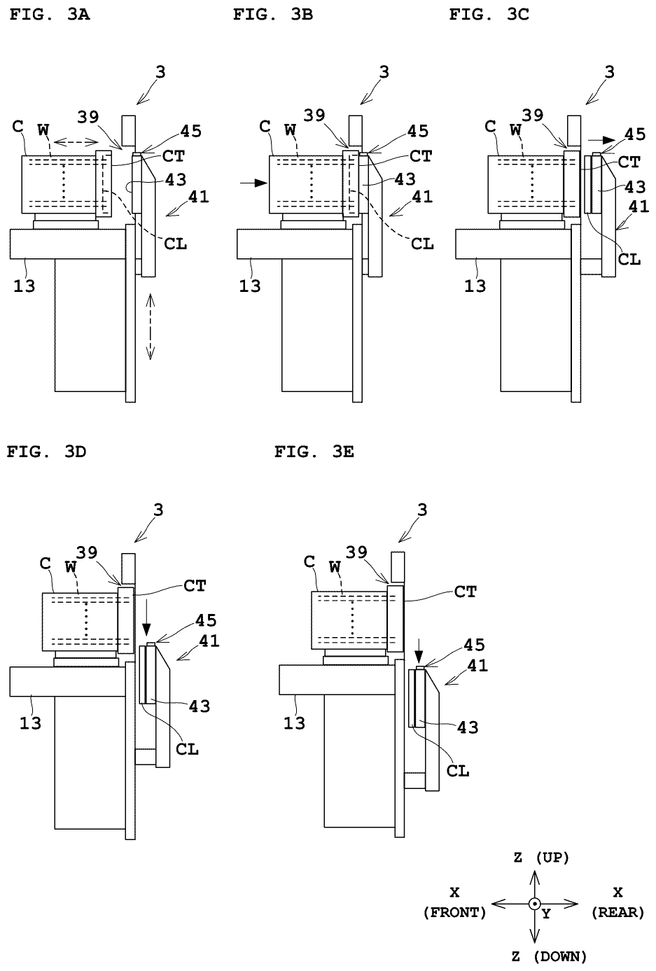

FIGS. 3A to 3E are side views illustrating a configuration and an operation of a loading/unloading block;

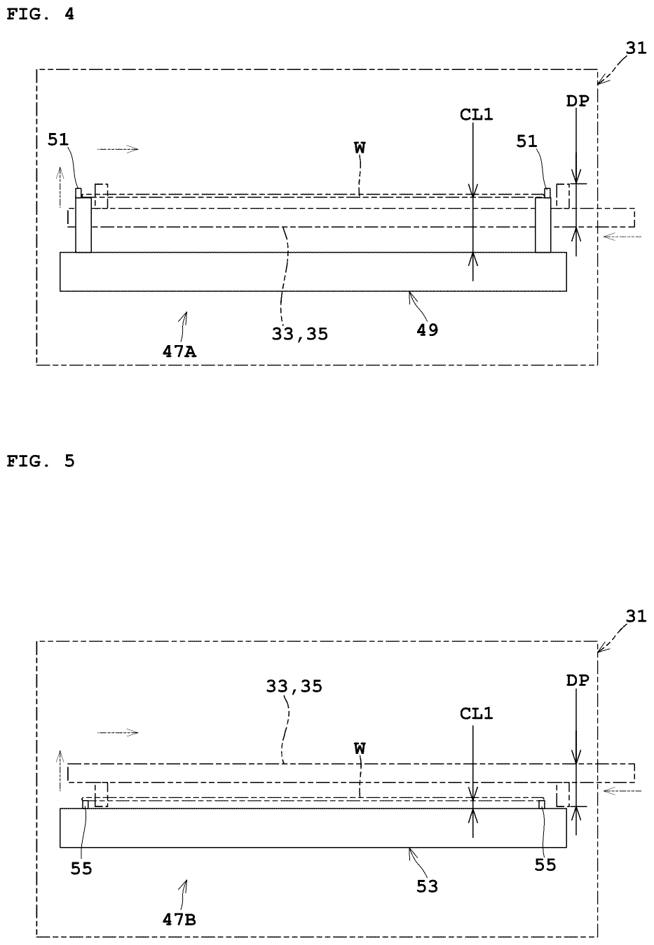

FIG. 4 is a side view illustrating a first example of a placement part included in a processing unit;

FIG. 5 is a side view illustrating a second example of the placement part included in the processing unit;

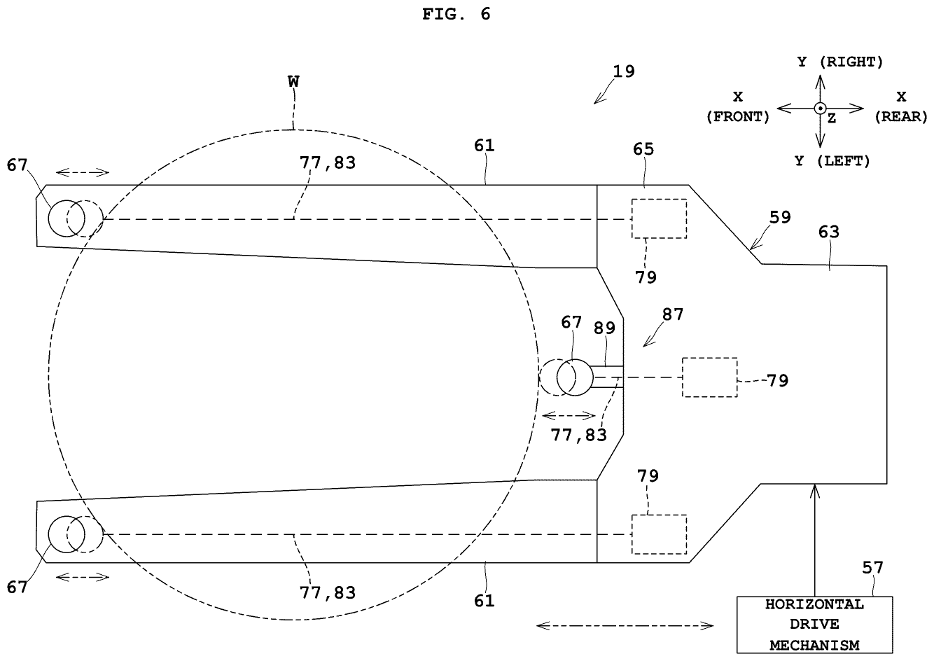

FIG. 6 is a plan view of a lower holding hand according to the first embodiment;

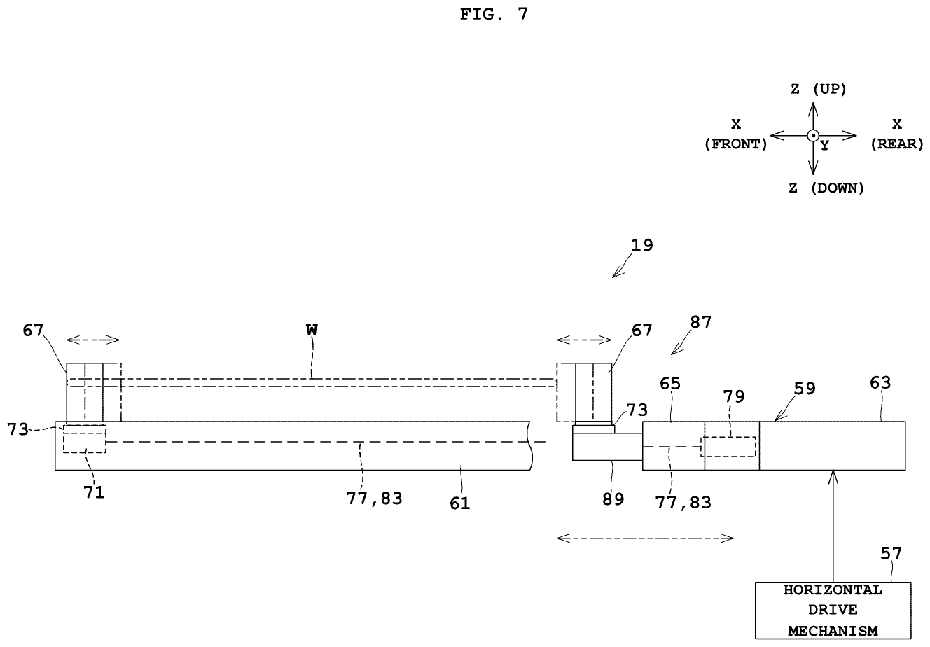

FIG. 7 is a side view of the hand according to the first embodiment;

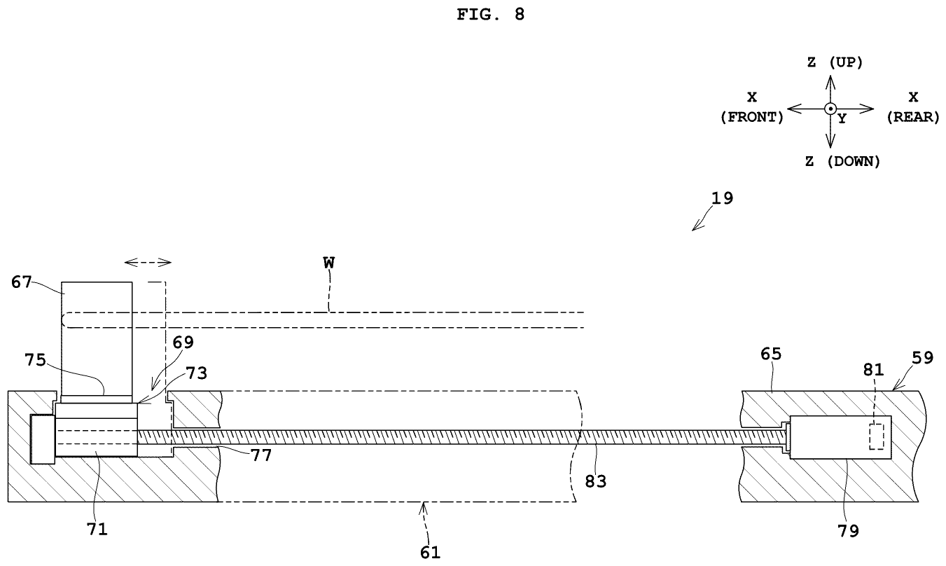

FIG. 8 is a longitudinal sectional view illustrating a configuration of a movable guide on a distal end side;

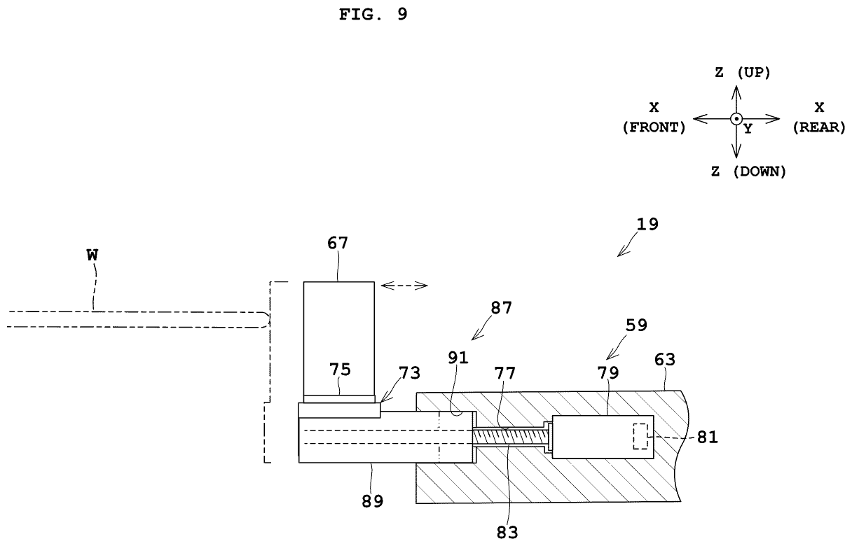

FIG. 9 is a longitudinal sectional view illustrating a configuration of a movable guide (pusher) on a proximal end side;

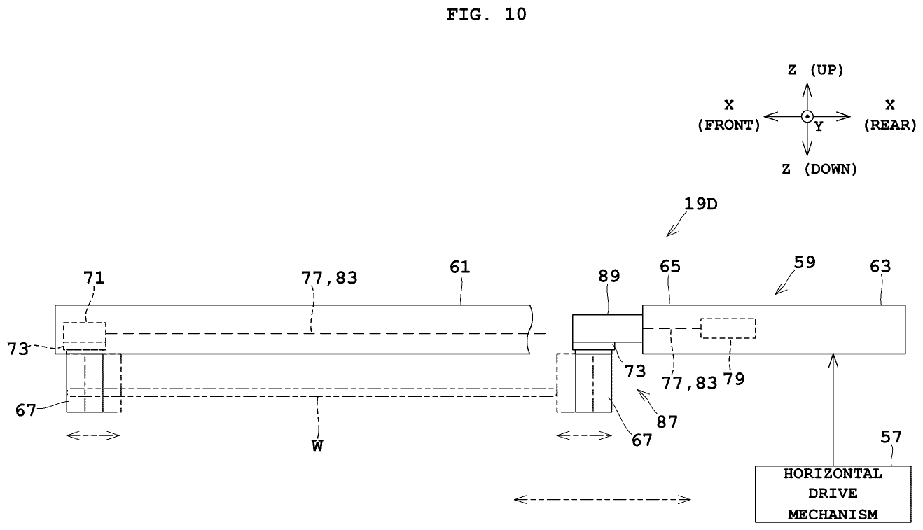

FIG. 10 is a side view of an upper holding hand according to the embodiment;

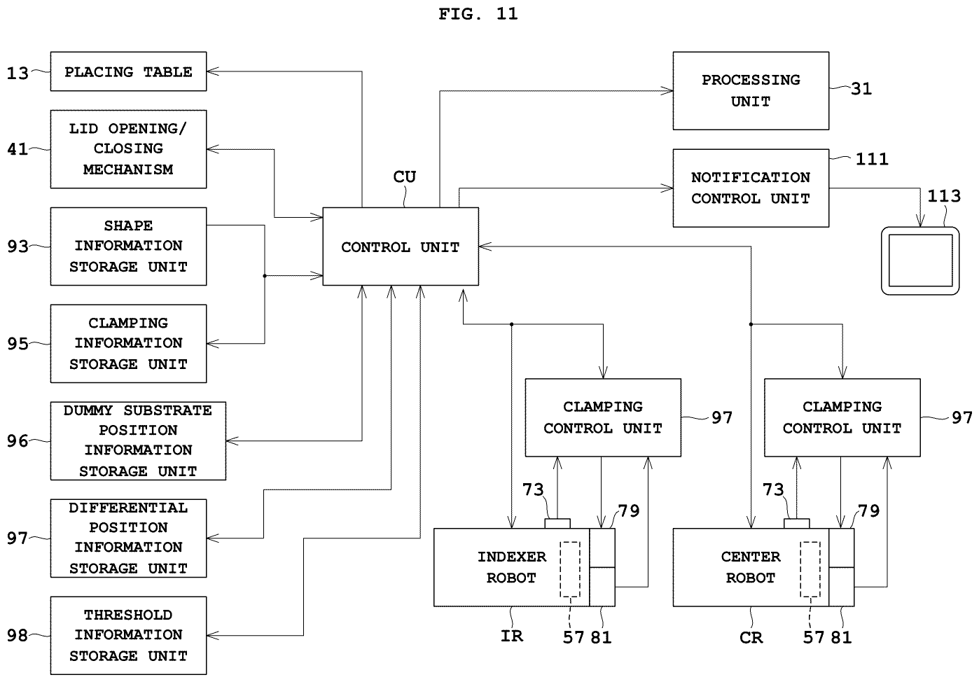

FIG. 11 is a block diagram illustrating a control system;

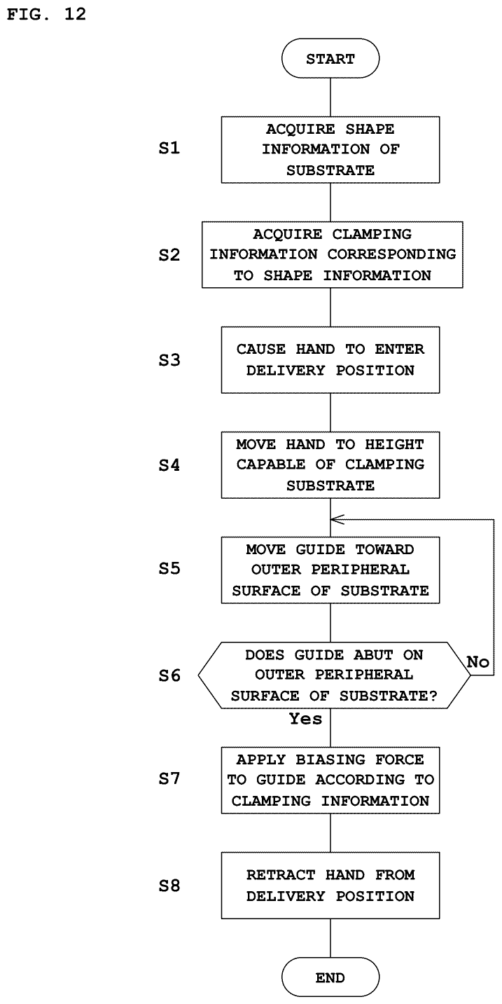

FIG. 12 is a flowchart for explaining an operation related to transfer;

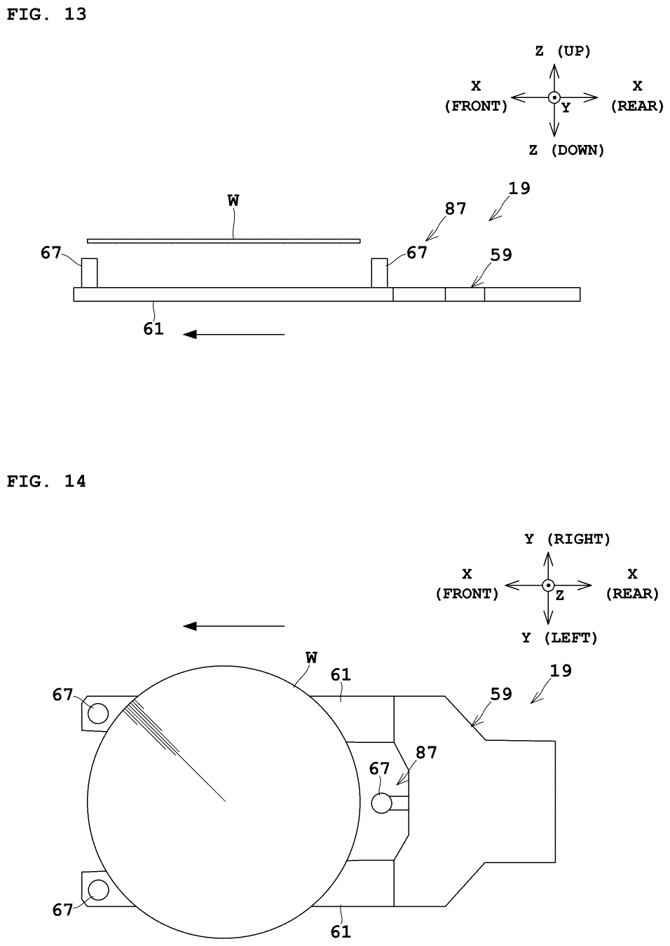

FIG. 13 is a schematic view for explaining the operation in side view;

FIG. 14 is a schematic view for explaining the operation in plan view;

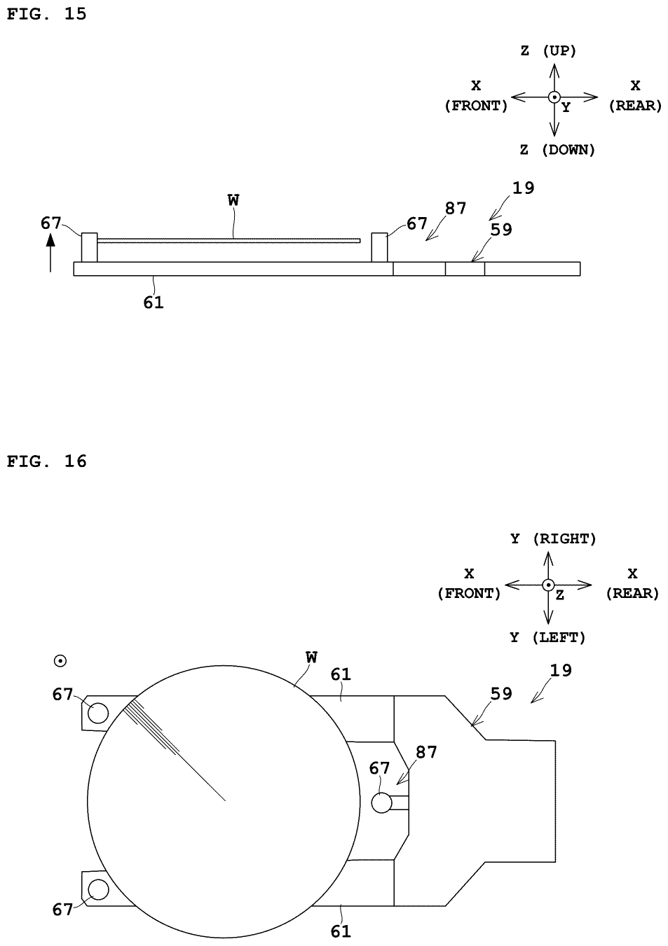

FIG. 15 is a schematic view for explaining the operation in side view;

FIG. 16 is a schematic view for explaining the operation in plan view;

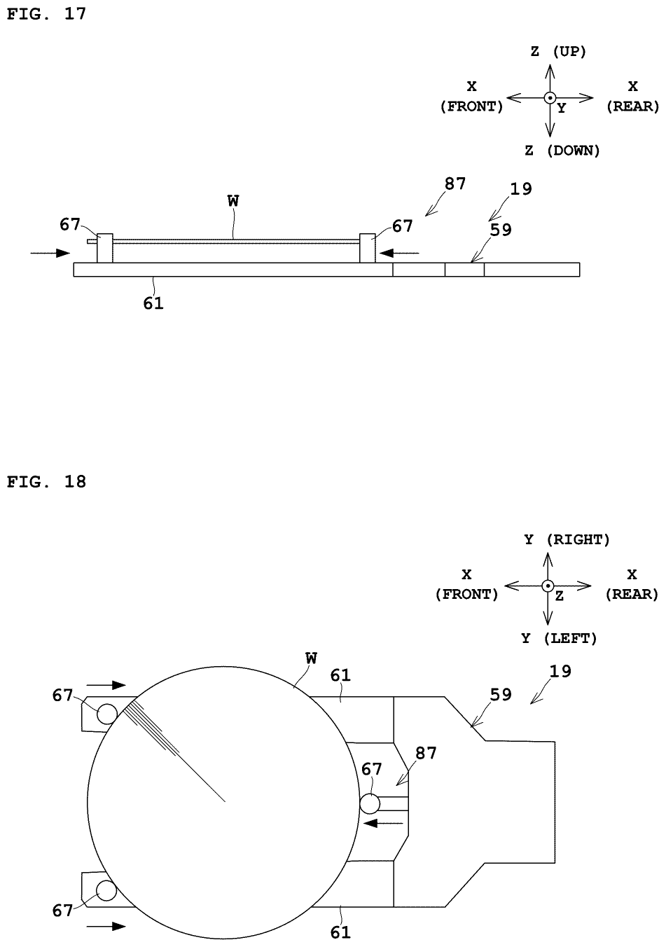

FIG. 17 is a schematic view for explaining the operation in side view;

FIG. 18 is a schematic view for explaining the operation in plan view;

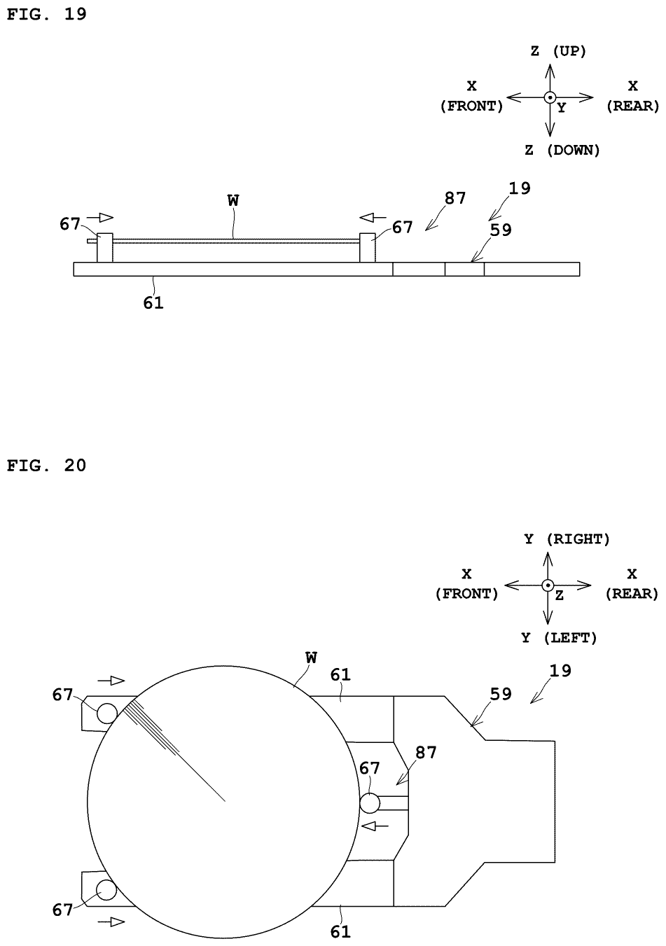

FIG. 19 is a schematic view for explaining the operation in side view;

FIG. 20 is a schematic view for explaining the operation in plan view;

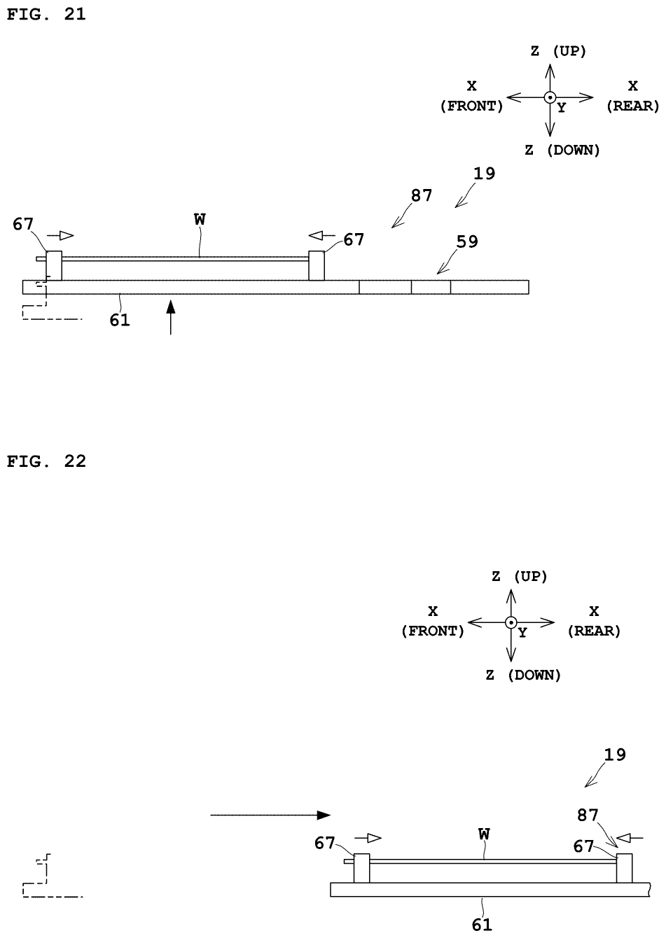

FIG. 21 is a schematic view for explaining the operation in side view;

FIG. 22 is a schematic view for explaining the operation in side view;

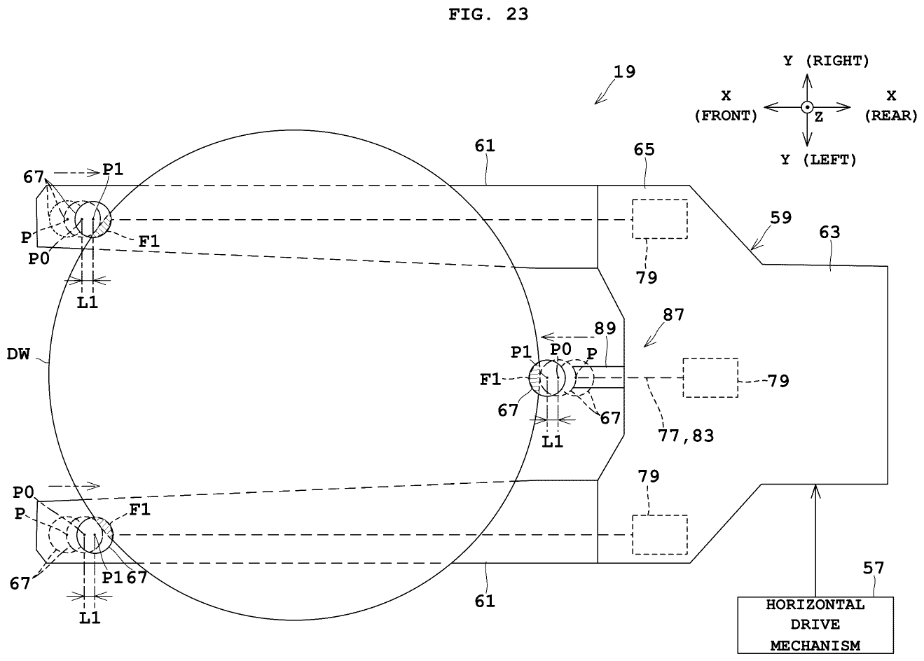

FIG. 23 is a plan view of the hand for explaining a first consumption degree of the guide;

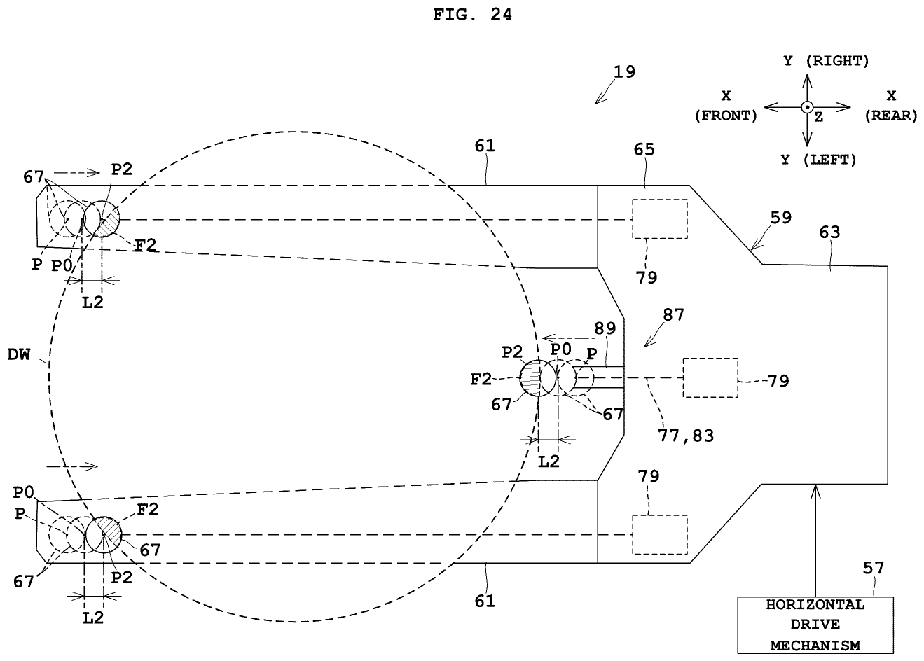

FIG. 24 is a plan view of the hand for explaining a second consumption degree of the guide;

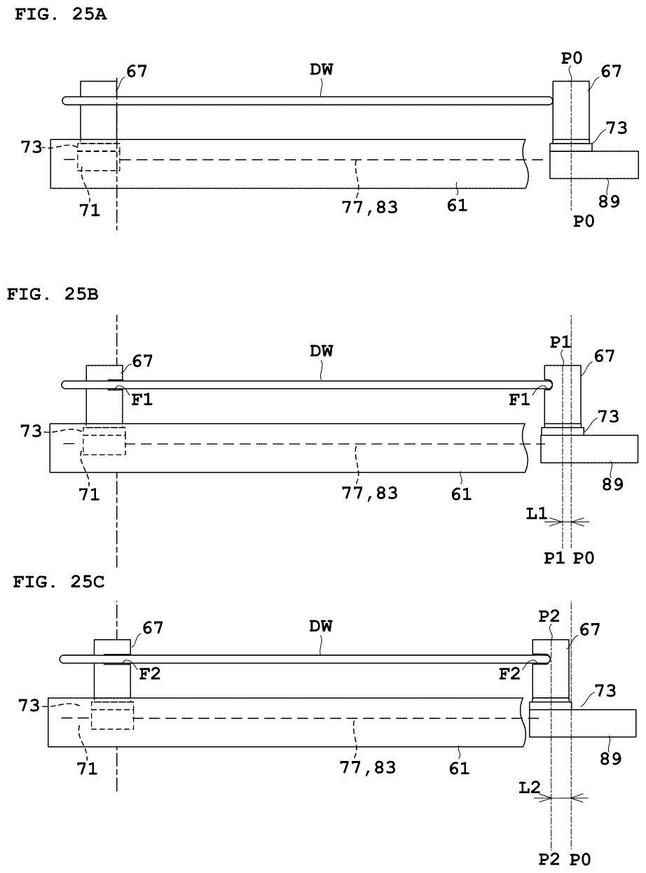

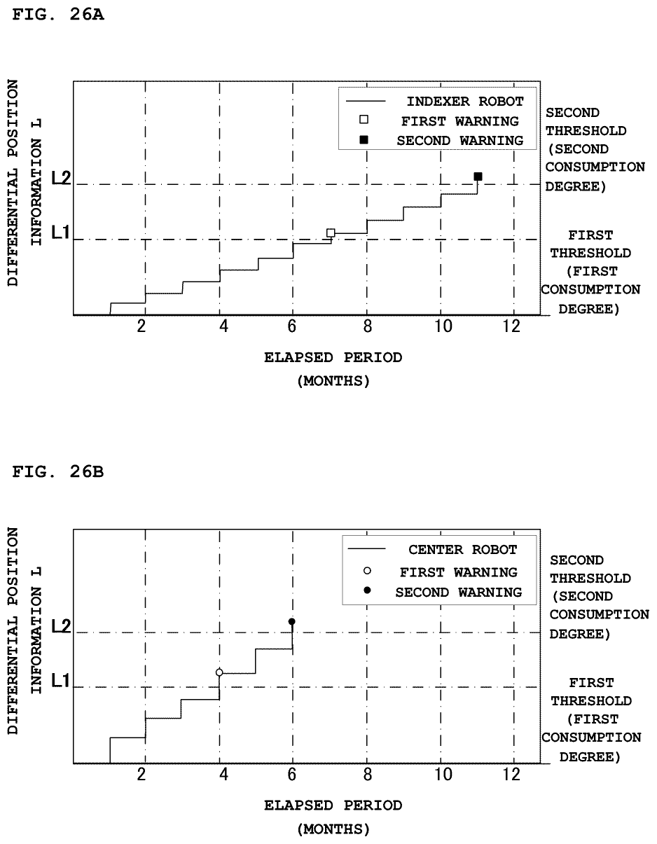

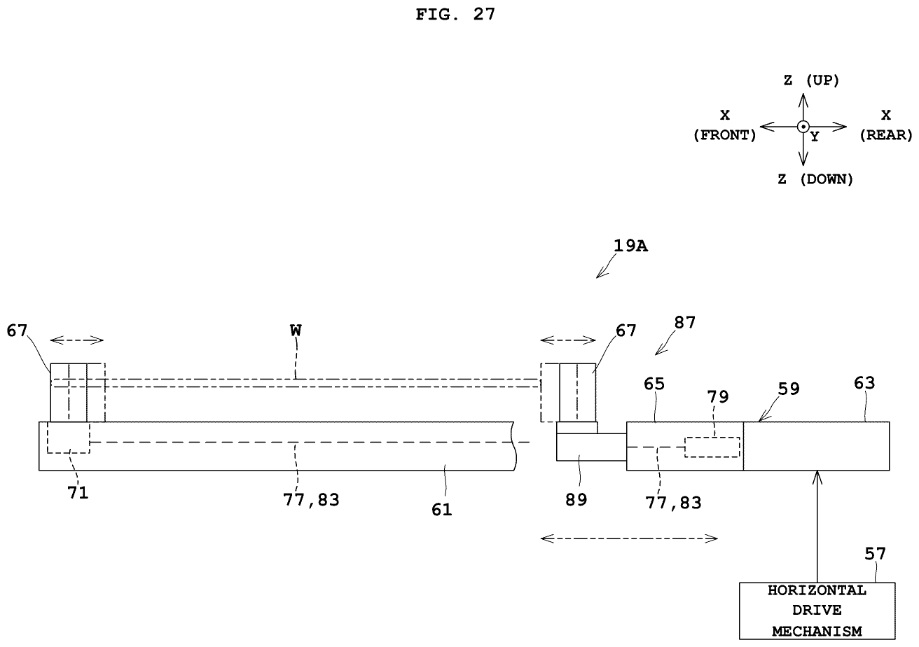

FIGS. 25A to 25C are side views of the hand for explaining the first and second consumption degrees of the guide;

FIGS. 26A and 26B are graphs illustrating the relationship between the consumption degree of the guide and the elapsed period;

FIG. 27 is a side view of the hand in the substrate processing apparatus according to a second embodiment;

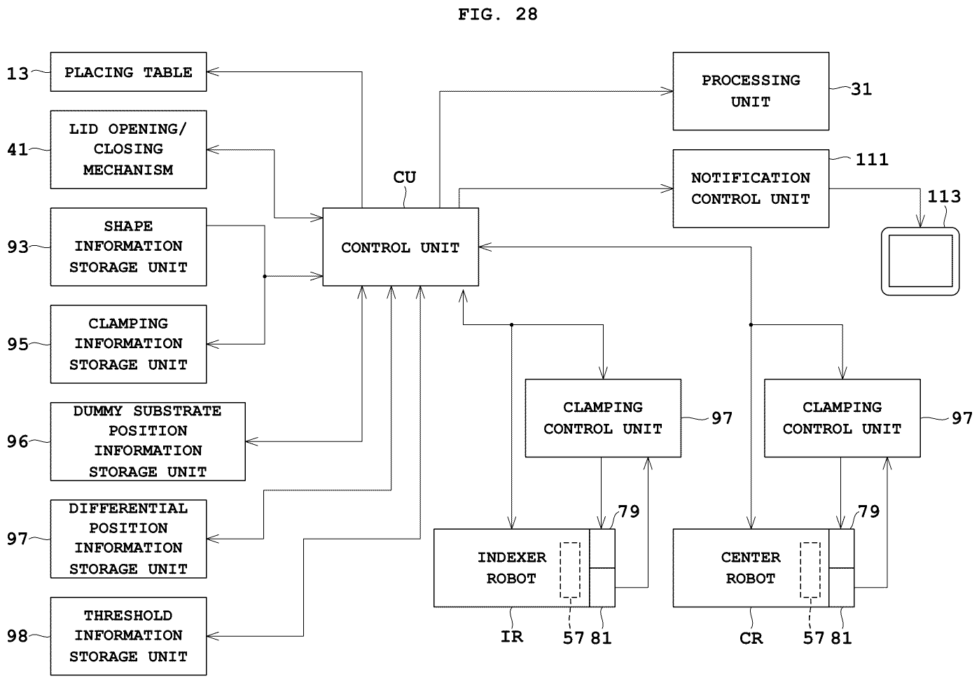

FIG. 28 is a block diagram illustrating a control system in the substrate processing apparatus according to the second embodiment;

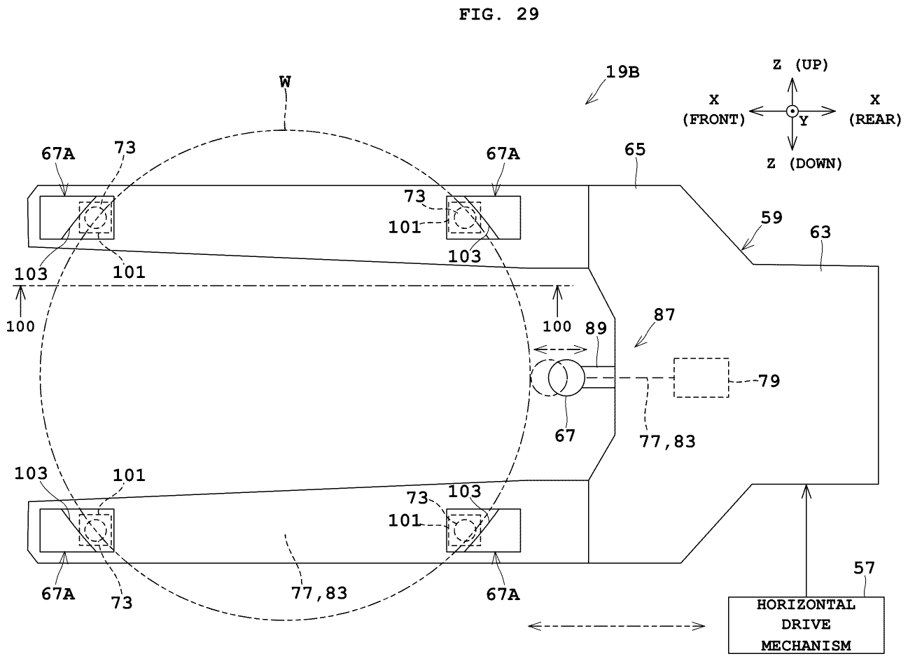

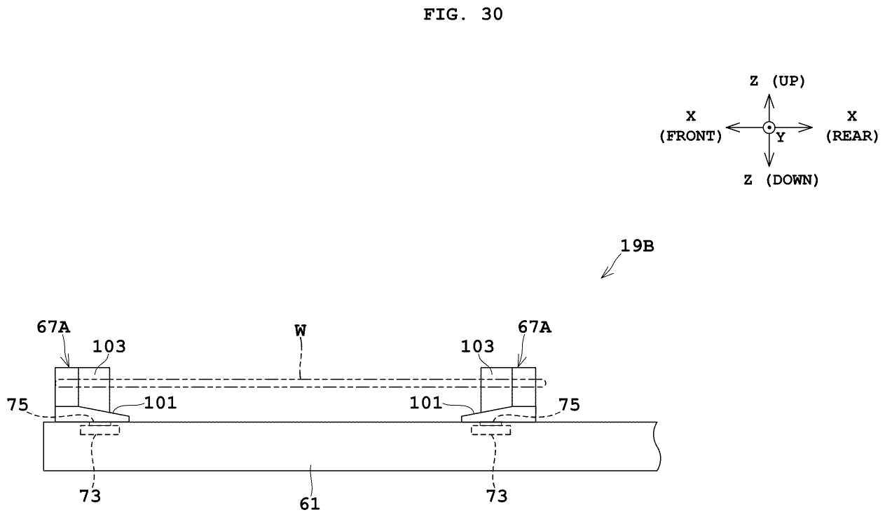

FIG. 29 is a plan view of the hand in a substrate processing apparatus according to a third embodiment;

FIG. 30 is a view taken in the direction of arrow 100-100 in FIG. 29;

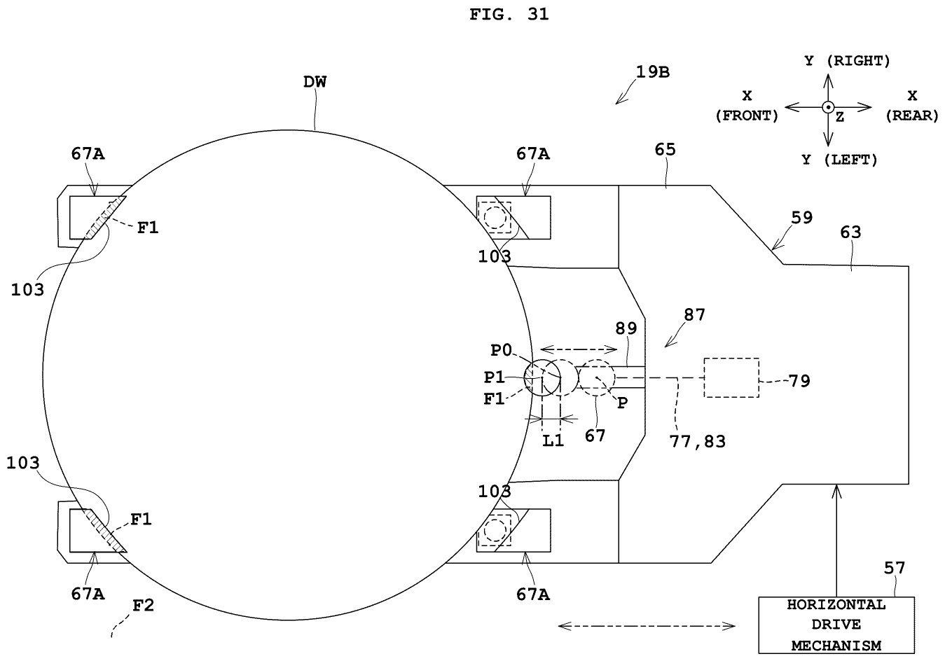

FIG. 31 is a plan view of the hand for explaining the first consumption degree of the guide;

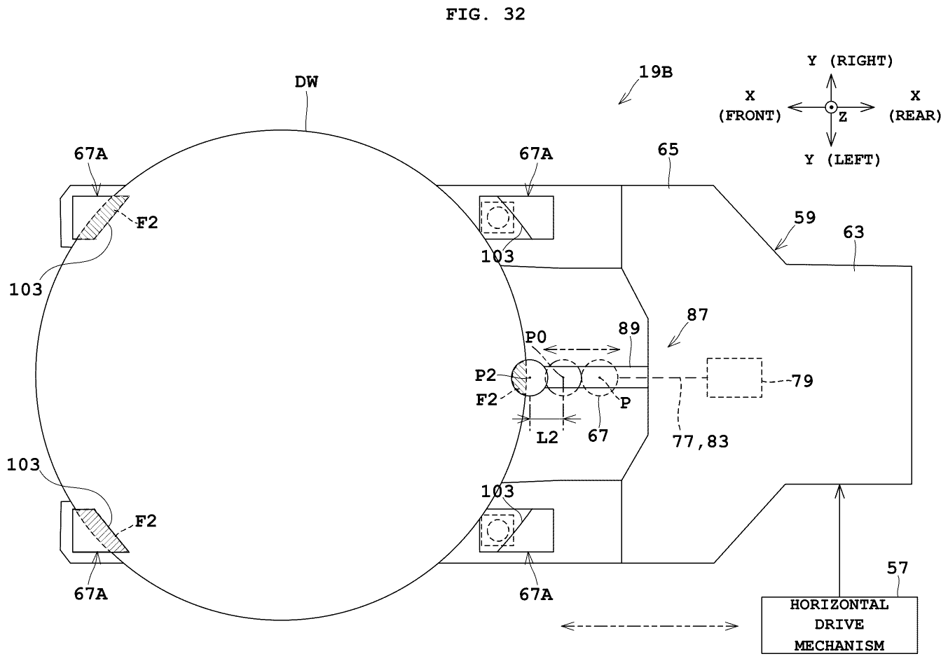

FIG. 32 is a plan view of the hand for explaining the second consumption degree of the guide;

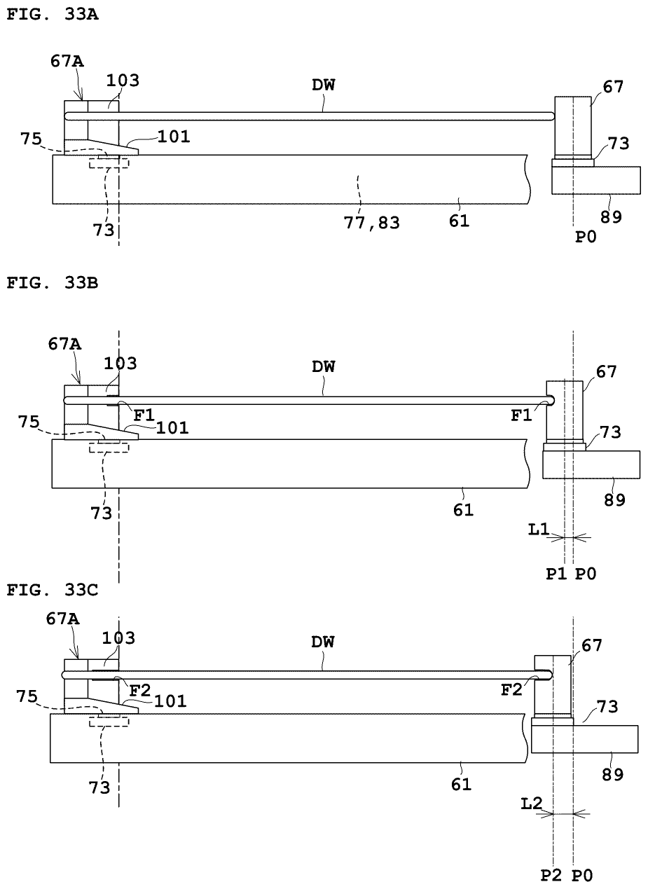

FIGS. 33A to 33C are side views of the hand for explaining the first and second consumption degrees of the guide;

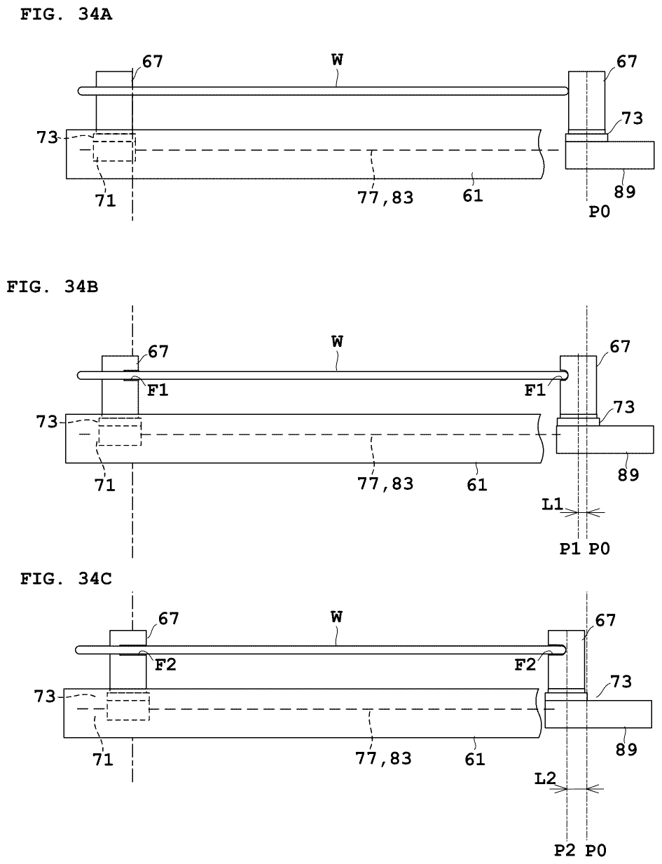

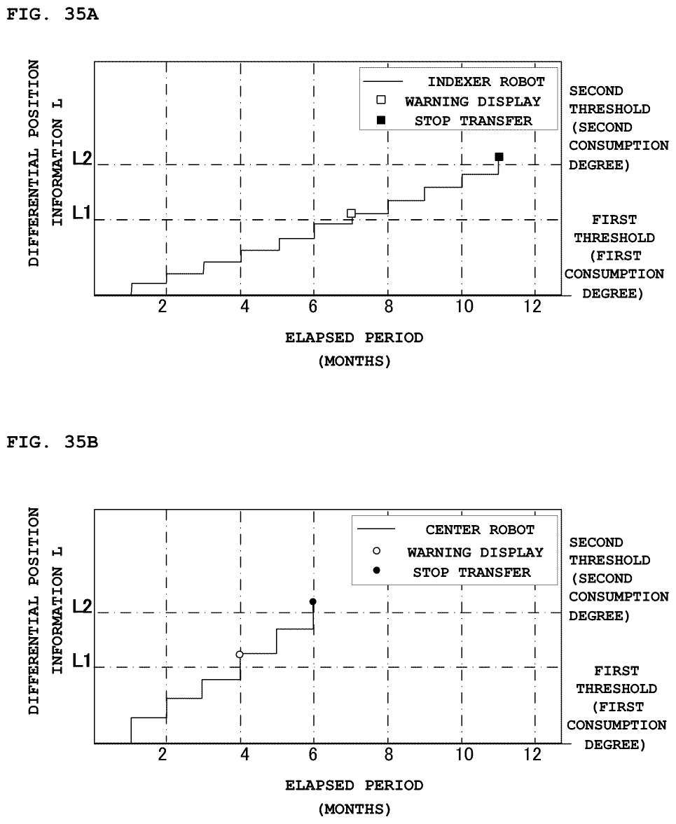

FIGS. 34A to 34C are side views of the hand for explaining the first and second consumption degrees of the guide of a fourth embodiment; and

FIGS. 35A and 35B are graphs illustrating the relationship between the consumption degree of the guide and the elapsed period.

### DESCRIPTION OF THE PREFERRED EMBODIMENTS

The present invention will be described below with reference to various embodiments.

### First Embodiment

Hereinafter, a first embodiment of the present invention will be described with reference to the drawings.

FIG. 1 is a plan view illustrating an overall configuration of a substrate processing apparatus according to the first embodiment. FIG. 2 is a view of the substrate processing apparatus of FIG. 1 as viewed from the rear side X.

### <1. Overall Configuration>

A substrate processing apparatus 1 includes a loading/unloading block 3, an indexer block 5, and a processing block 7.

The substrate processing apparatus 1 processes a substrate W. The substrate processing apparatus 1 performs, for example, cleaning processing on the substrate W. The substrate processing apparatus 1 processes the substrate W in a single wafer type in the processing block 7. In the single wafer type, one substrate W is processed one by one in a horizontal posture. The substrate W has, for example, a circular shape in plan view.

In the present specification, for convenience, a direction in which the loading/unloading block 3, the indexer block 5, and the processing block 7 are arranged is referred to as a “front-rear direction X”. The front-rear direction X is horizontal. In the front-rear direction X, the direction from the processing block 7 toward the loading/unloading block 3 is referred to as a “front side”. A direction opposite to the front side is referred to as a “rear side”. A horizontal direction orthogonal to the front-rear direction X is referred to as a “width direction Y”. One direction in the “width direction Y” is appropriately referred to as a “right side”. A direction opposite to the right side is referred to as a “left side”. A direction perpendicular to the horizontal direction is referred to as a “vertical direction Z”. In each drawing, front, rear, right, left, up, and down are appropriately shown for reference.

### <2. Loading/Unloading Block>

The loading/unloading block 3 includes a feeding unit 9 and a dispensing unit 11. The feeding unit 9 and the dispensing unit 11 are disposed in the width direction Y. A plurality of (for example, 25 sheets) substrates W are stacked and stored in one carrier C at constant intervals in a horizontal posture. The carrier C storing the untreated substrate W is placed in the feeding unit 9. The feeding unit 9 includes, for example, two placing tables 13 on which the carrier C is placed. In the carrier C, a plurality of grooves (not illustrated) for accommodating the substrates W one by one are formed with the surfaces of the substrates W separated from each other. The carrier C is accommodated, for example, in a posture in which the surface of the substrate W faces upward. As the carrier C, for example, there is a front opening unify pod (FOUP). The FOUP is a sealed container. The carrier C may be an open type container and may be of any type.

The dispensing unit 11 is disposed on the opposite side of the feeding unit 9 across the central portion in the width direction Y in the substrate processing apparatus 1. The dispensing unit 11 is disposed on the left side Y of the feeding unit 9. The dispensing unit 11 stores the processed substrate W in the carrier C and dispenses the processed substrate W together with the carrier C. Similarly to the feeding unit 9, the dispensing unit 11 functioning in this manner includes, for example, two placing tables 13 for placing the carrier C. The feeding unit 9 and the dispensing unit 11 are also called load ports.

### <3. Indexer Block>

The indexer block 5 is disposed adjacent to the rear side X of the loading/unloading block 3 in the substrate processing apparatus 1. The indexer block 5 includes an indexer robot IR and a delivery part 15.

The indexer robot IR is configured to be rotatable about the vertical direction Z. The indexer robot IR is configured to be movable in the width direction Y. The indexer robot IR includes a first hand 19 and a second hand 21. FIG. 1 illustrates only one hand for the sake of illustration. The first hand 19 and the second hand 21 hold the substrate W in a horizontal posture. The first hand 19 and the second hand 21 clamp the outer peripheral surface of the substrate W and hold the substrate W to be separated from the upper surfaces of the first hand 19 and the second hand 21.

Each of the first hand 19 and the second hand 21 holds one substrate W. The first hand 19 and the second hand 21 are independently movable forward and backward in the front-rear direction X. The indexer robot IR moves in the width direction Y and rotates around the vertical direction Z, and advances and retracts the first hand 19 and the second hand 21 to deliver the substrate W to and from each carrier C. Similarly, the indexer robot IR delivers the substrate W to and from the delivery part 15.

The delivery part 15 is disposed at a boundary with the processing block 7 in the indexer block 5. The delivery part 15 is disposed, for example, at a central portion in the width direction Y. As illustrated in FIG. 2, the delivery part 15 is formed to be long in the vertical direction Z.

The delivery part 15 includes a first reversing unit 23, a path part 25, a path part 27, a second reversing unit 29, and a dummy substrate placement part 30 from below to above in the vertical direction z.

The first reversing unit 23 vertically reverses the substrate W received from the indexer block 5. The first reversing unit 23 reverses the horizontal posture of the substrate W. Specifically, the first reversing unit 23 converts the substrate W with the surface facing upward into a posture with the surface facing downward. In other words, the posture of the substrate W is changed so that the rear surface faces upward.

The second reversing unit 29 performs the reverse operation. That is, the second reversing unit 29 vertically reverses the substrate W received from the processing block 7. The second reversing unit 29 converts the substrate W with the surface facing downward into a posture with the surface facing upward. In other words, the posture of the substrate W is changed so that the rear surface faces downward.

The reversing directions of the first reversing unit 23 and the second reversing unit 29 may be opposite to each other. That is, the first reversing unit 23 changes the posture of the substrate W so that the surface faces upward. The second reversing unit 29 changes the posture of the substrate W so that the rear surface faces upward.

The path parts 25 and 27 are used to deliver the substrates W between an indexer block 5 and the processing block 7. The path part 25 is used, for example, to transfer the substrate W from the processing block 7 to the indexer block 5. The path part 27 is used, for example, to transfer the substrate W from the indexer block 5 to the processing block 7. Note that the transfer directions of the substrates W in the path parts 25 and 27 may be opposite to each other.

A dummy substrate DW clamped by the guide 67 is placed in the dummy substrate placement part 30 in order to detect the consumption degree of the guide 67 described later. The dummy substrate DW may be clamped by the guide 67 of the indexer robot IR or may be clamped by the guide 67 of the center robot CR.

### <4. Processing Block>

The processing block 7 performs, for example, various types of processing on the substrate W. Examples of the processing include cleaning processing. The cleaning processing is, for example, treatment liquid cleaning processing performed by supplying only a cleaning liquid, or brush cleaning processing using a brush in addition to the treatment liquid.

As illustrated in FIG. 1, for example, the processing block 7 is divided into a first row R1, a second row R2, and a third row R3 in the width direction Y. Specifically, the first row R1 is disposed on the left side Y. The second row R2 is disposed at the central portion in the width direction Y. In other words, the second row R2 is disposed on the right side Y of the first row R1. The third row R3 is disposed on the right side Y of the second row R2.

### <4-1. First Row>

The first row R1 of the processing block 7 includes a plurality of processing units 31. The first row R1 includes, for example, four processing units 31. The first row R1 is arranged by stacking four processing units 31 in the vertical direction Z. Each processing unit 31 is, for example, a cleaning unit. The cleaning unit cleans the substrate W. Examples of the cleaning unit include a front surface cleaning unit for cleaning the front surface of the substrate W and a rear surface cleaning unit for cleaning the rear surface of the substrate W. In the present embodiment, a rear surface cleaning unit SSR will be described as an example of the processing unit 31.

### <4-2. Second Row>

The second row R2 of the processing block 7 includes a center robot CR. The center robot CR is configured to be rotatable about the vertical direction Z. The center robot CR is configured to be movable up and down in the vertical direction Z. The center robot CR includes, for example, a first hand 33 and a second hand 35. Each of the first hand 33 and the second hand 35 holds one substrate W. The first hand 33 and the second hand 35 are independently movable forward and backward in the front-rear direction X and the width direction Y.

The first hand 33 and the second hand 35 hold the substrate W in a horizontal posture. The first hand 33 and the second hand 35 clamp the outer peripheral surface of the substrate W and hold the substrate W to be separated from the upper surfaces of the first hand 33 and the second hand 35.

### <4-3. Third Row>

The third row R3 of the processing block 7 has the same configuration as the first row R1. That is, the third row R3 includes the plurality of processing units 31. The third row R3 includes, for example, four processing units 31. The third row R3 is arranged by stacking four processing units 31 in the vertical direction Z. The processing units 31 in the first row R1 and the processing units 31 in the third row R3 are arranged to face each other in the width direction Y. As a result, the center robot CR can access the processing units 31 facing the first row R1 and the third row R3 at the same height in the vertical direction Z.

The processing block 7 is configured as described above. Here, an operation example of the center robot CR will be briefly described. The center robot CR receives the substrate W from the first reversing unit 23, for example. The center robot CR transfers the substrate W to the rear surface cleaning unit SSR in one of the first row R1 and the third row R3, and causes the rear surface of the substrate W to be cleaned. The center robot CR receives the substrate W subjected to the cleaning processing in the rear surface cleaning unit SSR in any one of the first row R1 and the third row R3. The center robot CR transfers the substrate W to the second reversing unit 29. The indexer robot IR receives the substrate W from the second reversing unit 29 and stores the substrate W in the carrier C.

Note that the dummy substrate DW described above is a substrate that is not processed by the processing unit 31 described above. The dummy substrate DW is a substrate used for measuring the consumption degree of the guide 67 and adjusting the position of the hand of the indexer robot IR or the center robot CR.

### <5. Placing Table>

Here, the above-described loading/unloading block 3 will be described in detail with reference to FIGS. 1, and 3A to 3E. FIGS. 3A to 3E are side views illustrating a configuration and an operation of the loading/unloading block.

The loading/unloading block 3 includes a placing table 13, an opening 39, and a lid opening/closing mechanism 41. The carrier C is placed on the placing table 13. The placing table 13 includes a mechanism (not illustrated) that moves the carrier C in the front-rear direction X. The placing table 13 can advance or retract the carrier C with respect to the opening 39. The carrier C has a loading/unloading port CT. The loading/unloading port CT is formed on one side surface of the carrier C. The plurality of substrates W stacked and accommodated in the carrier C are loaded and unloaded via the loading/unloading port CT. The carrier C includes a lid CL. The lid CL is configured to be detachable from the loading/unloading port CT of the carrier C. The lid CL seals the inside of the carrier C. When the lid CL is attached to the carrier C, the atmosphere from the outside of the carrier C is blocked.

The lid opening/closing mechanism 41 includes a detachable unit 43 on the front side X. The detachable unit 43 detaches the lid CL from the carrier C and attaches the lid CL to the carrier C. The detachable unit 43 is movable in the vertical direction Z and the front-rear direction X while holding the lid CL. The lid opening/closing mechanism 41 is movable in the front-rear direction X at the opening 39 in a state of holding the lid CL. The lid opening/closing mechanism 41 is movable up and down in the vertical direction Z in a state of holding the lid CL. The lid opening/closing mechanism 41 can move downward in the vertical direction Z from the opening 39 in a state of holding the lid CL. The lid opening/closing mechanism 41 can fully open the opening 39 by lowering in a state of holding the lid CL.

First, as illustrated in FIG. 3A, the carrier C is placed on the placing table 13. A plurality of substrates W are stacked and accommodated in the carrier C, and the carrier C is closed by the lid CL. At this time, the lid opening/closing mechanism 41 positions the detachable unit 43 in the opening 39. Accordingly, the inside of the indexer block 5 is separated from the external atmosphere.

As illustrated in FIG. 3B, the placing table 13 moves the carrier C to the rear side X. In the carrier C, the loading/unloading port CT and the lid CL are located in the opening 39. At this time, the detachable unit 43 unlocks the lid CL and holds the lid CL. The holding is performed, for example, by the detachable unit 43 sucking the lid CL.

As illustrated in FIG. 3C, the lid opening/closing mechanism 41 moves to the rear side X. Thus, the lid CL is moved from the opening 39 to the rear side X. The lid CL is moved to the inside of the indexer block 5.

As illustrated in FIG. 3D, the lid opening/closing mechanism 41 moves downward in the vertical direction Z. The lid opening/closing mechanism 41 lowers the detachable unit 43 to the lower part of the loading/unloading port CT. The lid opening/closing mechanism 41 is lowered until the upper portion of the detachable unit 43 is positioned at the lower portion of the opening 39.

As illustrated in FIG. 3E, the lid opening/closing mechanism 41 moves downward in the vertical direction Z, and moves to the lowermost portion where the lid opening/closing mechanism 41 can move. The lid opening/closing mechanism 41 is lowered to a position where the detachable unit 43 does not overlap the opening 39 in the front-rear direction X. As a result, the opening 39 is fully opened. The plurality of substrates W in the carrier C can face the indexer block 5 through the opening 39.

The lid opening/closing mechanism 41 described above includes, for example, the substrate sensor 45 in the detachable unit 43. The substrate sensor 45 is used to detect the position of the substrate W stacked and stored in the carrier C and collect shape information based on the outer edge of the substrate W. The shape information includes information regarding the thickness based on the outer edge of the substrate W.

### <6. Placement Part>

Here, a part of the processing unit 31 described above will be described with reference to FIGS. 4 and 5. FIG. 4 is a side view illustrating a first example of the placement part included in the processing unit. FIG. 5 is a side view illustrating a second example of the placement part included in the processing unit.

The processing unit 31 described above is the rear surface cleaning unit SSR. Such a rear surface cleaning unit SSR includes, for example, one of two types of placement parts 47 (placement parts 47A, 47B) as described below. The placement part 47 is a place where the substrate W is placed in the rear surface cleaning unit SSR. The placement part 47 supports the lower surface of the substrate W. In addition to such two types of placement parts 47 (placement parts 47A, 47B), there is also a placement part that holds the substrate W by suction.

As illustrated in FIG. 4, the placement part 47A includes a turning table 49 and a support pin 51. The turning table 49 has a circular shape in plan view. The turning table 49 has a diameter slightly larger than that of the substrate W. A plurality of support pins 51 are provided. The support pin 51 is erected on the upper surface of the turning table 49. The support pin 51 is disposed on an upper surface slightly inside the outer peripheral surface of the turning table 49. Some of the support pins 51 rotate eccentrically about the axis in the vertical direction Z. The substrate W is pressed in the horizontal direction from the outer peripheral surface by the support pins 51 rotating in this manner, and the position is fixed by the plurality of support pins 51. The support pins 51 abuts on the outer peripheral surface and the lower surface of the substrate W to support the lower surface of the substrate W to be separated from the upper surface of the turning table 49.

Here, the interval between the upper surface of the turning table 49 and the lower surface of the substrate W supported by the support pins 51 is referred to as a clearance CL1. The placement part 47A in the first example has a relatively large clearance CL1. The clearance CL1 is larger than the thicknesses DP of the first hand 33 and the second hand 35. The thickness DP corresponds to the maximum height in the vertical direction Z in a case where a portion of the first hand 33 and the second hand 35 which enters the position to deliver the substrate W is viewed from the side.

In the cleaning unit SSR including such a placement part 47A, it is preferable to access with a lower holding hand described later. The placement part 47A can be accessed by an upper holding hand described later.

As illustrated in FIG. 5, the placement part 47B includes a turning table 53 and a support projection 55. The turning table 53 has a circular shape in plan view. The turning table 53 includes an injection port (not illustrated) for supplying gas to the lower surface of the substrate W. The support projection 55 is formed on the upper surface of the turning table 53. The plurality of support projections 55 are provided. The support projection 55 is formed slightly inside the outer peripheral surface of the turning table 53. The support projections 55 abut on the lower surface of the substrate W to support the lower surface of the substrate W to be separated from the upper surface of the turning table 53. The substrate W is supported so as to be sucked by the support projections 55 and the turning table 53 by a negative pressure generated by supplying gas. As a result, the position of the substrate W is fixed. A clearance CL2 of the placement part 47B is relatively small. The clearance CL2 is smaller than the clearance CL1. The clearance CL2 is smaller than the thicknesses DP of the first hand 33 and the second hand 35.

In the cleaning unit SSR including such a placement part 47A, it is preferable to access with an upper holding hand described later.

### <7. Details of Hand>

Here, the first hand 19 in the indexer robot IR will be described as an example with reference to FIGS. 6 to 10. Note that the configuration of the first hand 19 is the same as that of the second hand 21 and the first hand 33 and the second hand 35 in the center robot CR.

The indexer robot IR includes a horizontal drive mechanism 57. The horizontal drive mechanism 57 drives the first hand 19 in the front-rear direction X. The horizontal drive mechanism 57 drives the first hand 19 to be advanced or retracted in the horizontal direction. The horizontal drive mechanism 57 drives the first hand 19 to be advanced or retracted with respect to the delivery destination. Specifically, the delivery destination in the indexer robot IR is driven forward and backward with respect to the carrier C and the delivery part 15. The horizontal drive mechanism 57 in the center robot CR drives the first hand 33 and the second hand 35 forward and backward in the front-rear direction X and also in the width direction Y.

The first hand 19 includes one palm portion 59 and two finger portions 61. The palm portion 59 is a proximal end side of the first hand 19. The finger portion 61 is on the distal end side of the first hand 19. The delivery destination enters from the distal end side of the first hand 19 and exits from the proximal end side of the first hand 19. The palm portion 59 includes an attachment proximal end section 63 and a finger attachment section 65. The attachment proximal end section 63 is attached to the horizontal drive mechanism 57. The finger portions 61 are attached to the finger attachment sections 65. The finger attachment sections 65 are provided at two positions spaced apart in the width direction Y. The portion of the finger attachment sections 65 to which the two finger portions 61 are attached are located outside the outer peripheral surface of the substrate W in plan view when the first hand 19 advances to the position to deliver the substrate W. In other words, the length of the finger portion 61 in the front-rear direction X is longer than the diameter of the substrate W.

The first hand 19 includes two finger portions 61. The two finger portions 61 extend in the front-rear direction X. The two finger portions 61 are separated from each other in the width direction Y. The distance by which the two finger portions 61 are separated from each other does not exceed the diameter of the substrate W. In other words, the width direction Y of the two finger portions 61 falls within the diameter of the substrate W. The proximal end side of the finger portion 61 is attached to the finger attachment section 65. The distal end side on the opposite side of the proximal end side of the finger portion 61 is in an open state. The first hand 19 has a U shape in plan view with the palm portion 59 and the two finger portions 61.

The first hand 19 includes three guides 67. Three guides 67 are attached to the upper surface of the first hand 19. The finger portion 61 includes one guide 67 on the distal end side. A structure in which the guide 67 is attached to the upper surface of the finger portion 61 like the first hand 19 is referred to as a “lower holding hand”. The first hand 19 having a structure of the lower holding hand holds the substrate W by scooping up the substrate W from below to above.

As illustrated in FIG. 8, the guide 67 of the finger portion 61 is attached to the guide hole 69. The guide hole 69 is long in the front-rear direction X. A movable piece 71 is disposed at the bottom of the guide hole 69. The movable piece 71 is movable only in the front-rear direction X at the bottom of the guide hole 69. A tactile sensor 73 is attached to the movable piece 71. The tactile sensor 73 is attached to the upper surface of the movable piece 71.

The tactile sensor 73 has a detection surface 75 capable of detecting force applied to each of three axes orthogonal to each other. The tactile sensor 73 is attached to the movable piece 71 in a posture in which the detection surface 75 is directed upward. The guide 67 is attached to the detection surface 75. The bottom of the guide 67 is attached to the detection surface 75. The tactile sensor 73 can detect the force applied to the guide 67 in each of the three axial directions. The tactile sensor 73 detects forces applied in the front-rear direction X, the width direction Y, and the vertical direction Z. The tactile sensor 73 outputs electrical signals corresponding to the respective forces detected in the three axial directions.

In the finger portion 61, a lateral hole 77 is formed in the front-rear direction X from the guide hole 69. The lateral hole 77 penetrates to the palm portion 59. In the palm portion 59, a servomotor 79 is provided at a position corresponding to an end portion of the lateral hole 77. The servomotor 79 includes an encoder 81. The encoder 81 detects a rotational position (rotation angle) of the rotation shaft of the servomotor 79, and outputs the rotational position as position information in the form of an electric signal. A ball screw 83 is inserted into the lateral hole 77. One end side of the ball screw 83 is connected to the rotation shaft of the servomotor 79. The movable piece 71 is screwed to the other end side of the ball screw 83. When the servomotor 79 is rotationally driven, the ball screw 83 is rotated, and the movable piece 71 moves in the front-rear direction X along the guide hole 69. As a result, the guide 67 moves in the front-rear direction X.

As illustrated in FIG. 9, the palm portion 59 includes a pusher 87. The pusher 87 includes one guide 67. The pusher 87 has the same configuration as the configuration for driving the guide 67 of the finger portion 61 except for a pusher arm 89 and a guide hole 91.

That is, the pusher 87 includes the tactile sensor 73, the lateral hole 77, the ball screw 83, the servomotor 79, the encoder 81, and the pusher arm 89. One end side of the lateral hole 77 penetrates a side surface on the finger portion 61 side. The guide hole 91 is formed on the finger portion 61 side of the lateral hole 77. The guide hole 91 has a larger dimension in the vertical direction Z than the lateral hole 77. A part of the pusher arm 89 is inserted into the guide hole 91 so as to be movable in the front-rear direction X. The other end side of the lateral hole 77 is closed inside the palm portion 59. The servomotor 79 is disposed on the other end side of the lateral hole 77. The servomotor 79 includes the encoder 81. One end side of the ball screw 83 is connected to the rotation shaft of the servomotor 79. The pusher arm 89 is screwed to the other end side of the ball screw 83. The pusher arm 89 includes the tactile sensor 73 on the opposite side of the servomotor 79 in the front-rear direction X. The guide 67 is attached to the detection surface 75 of the tactile sensor 73.

Each guide 67 described above is configured to be movable by a predetermined distance in the front-rear direction X. Each guide 67 described above is movable, for example, by a distance of about 5 mm in the front-rear direction X.

The first hand 19 includes three guides 67 on the upper surface. The first hand 19 holds the substrate W in a state where the lower surface of the substrate W is separated upward from the upper surface of the finger portion 61. Specifically, the outer peripheral surface of the substrate W is clamped by the three guides 67, and the lower surface of the substrate W is held in a state of floating from the upper surface of the finger portion 61. The first hand 19 holds the substrate W in a state of abutting on only the outer peripheral surface of the substrate W. The first hand 19 moves the three guides 67 toward the outer peripheral surface of the substrate W to clamp the outer peripheral surface of the substrate W with the three guides 67, and holds the substrate W in a state of being separated from the upper surface of the finger portion 61.

The first hand 19 includes three guides 67 on the upper surface, but may be configured as illustrated in FIG. 10. FIG. 10 is a side view of the lower holding hand according to the embodiment.

Unlike the first hand 19, three guides 67 are attached to the lower surface in a first hand 19D. Specifically, each of the two finger portions 61 has one guide 67 on the distal end side on the lower surface. The palm portion 59 includes one guide 67 on the lower surface on the distal end side. The first hand 19D is referred to as an “upper holding hand”. The first hand 19D, which is a structure of an upper holding hand, holds the substrate W so as to lift the substrate W upward from above.

The first hand 19D drives the three guides 67 with the same configuration except that the attachment surface of the guide 67 is different from that of the first hand 19 described above. Therefore, a detailed description of the drive mechanism will be omitted.

Each guide 67 described above is preferably made of, for example, PBI (polybenzimidazole). This is because PBI has high heat resistance, excellent chemical resistance, and robustness. However, each guide 67 may be made of another material. Examples of other materials include fluororesins such as PTFE (polytetrafluoroethylene) and PFA (perfluoroalkoxy alkane).

### <8. Control System>

A control system of the substrate processing apparatus 1 described above will be described with reference to FIG. 11. FIG. 11 is a block diagram illustrating a control system.

The substrate processing apparatus 1 is integrally controlled by the control unit CU. The control unit CU includes a CPU, a memory, and the like. The control unit CU transfers the substrate W to the processing unit 31 on the basis of a recipe defining a processing procedure, conditions, and the like of the substrate W to perform processing.

A shape information storage unit 93 stores the shape information for each substrate W obtained by the substrate sensor 45 in association with the substrate W. The shape information includes the thickness of the substrate W. The shape information includes warpage of the substrate W. In the shape information storage unit 93, the shape information is referred to by the control unit CU.

The shape information storage unit 93 also stores the shape information of the dummy substrate DW described above. The shape information of the dummy substrate DW is used when the dummy substrate DW is clamped by the guide 67.

Clamping information storage unit 95 stores the center position of the substrate W according to the position of the guide 67 when the substrate W is held by the first hand 19. The center position of the substrate W is acquired by the control unit CU via a clamping control unit 97 to be described later and written in the clamping information storage unit 95 by the control unit CU.

The clamping information storage unit 95 also stores clamping information in advance according to the shape of the substrate W. The clamping information is associated with each piece of shape information of the substrate W. The clamping information is a biasing force applied to the guide 67. The clamping information is information related to the biasing force applied to the guide 67 by the servomotor 79. The biasing force applied from the guide 67 to the substrate W and the torque applied from the servomotor 79 to the ball screw 83 are smaller as the substrate W is thinner, for example. These biasing forces and torques are smaller, for example, as the substrate W warps. These biasing forces and torques are larger, for example, as the substrate W is not warped and is thicker.

The clamping information is a biasing force or torque in a case where the substrate W having various shapes is actually held by the first hand 19 in advance, the substrate W and the guide 67 are not damaged at that time, and the substrate W can be held so as not to fall. The clamping information may be stored in advance in a separate device (not illustrated) and downloaded from a host computer (not illustrated) via a network.

The clamping information storage unit 95 also stores clamping information in advance according to the shape of the dummy substrate DW described above. The clamping information of the dummy substrate DW is used when the dummy substrate DW is clamped by the guide 67.

The processing unit 31 includes the rear surface cleaning unit SSR and the like. The processing unit 31 includes the placement part 47A and the placement part 47B described above. Processing of the processing unit 31 is controlled by the control unit CU. The control unit CU stores in advance which processing unit 31 includes the placement part 47A and which processing unit 31 includes the placement part 47B.

The indexer robot IR is controlled by the control unit CU. Movement of the indexer robot IR in the front-rear direction X, the width direction Y, and the vertical direction Z is operated by the control unit CU. Movement of the first hand 19 and the second hand 21 in the front-rear direction X is operated by the control unit CU via the horizontal drive mechanism 57.

The clamping control unit 97 independently operates the movement of each of the three guides 67. The clamping control unit 97 is operated by the control unit CU. The clamping control unit 97 operates each servomotor 79 on the basis of an instruction from the control unit CU to independently move the three guides 67. At that time, the clamping control unit 97 operates the servomotor 79 according to the position information from the encoder 81. The clamping control unit 97 operates a drive current to the servomotor 79. The clamping control unit 97 can detect the drive current supplied to the servomotor 79.

In a case where the tactile sensor 73 detects that the guide 67 abuts on the outer peripheral surface of the substrate W, the 97 clamping control unit 97 adjusts the biasing force of the guide 67 to the outer peripheral surface of the substrate W according to the shape information from the shape information storage unit 93, and clamps the substrate W. At this time, the guide 67 does not necessarily move from the outer peripheral surface side to the center side of the substrate W. That is, the guide 67 may not move in the center direction of the substrate W only by increasing the torque of the servomotor 79 to strengthen the biasing force to the outer peripheral surface of the substrate W.

In a case where the first hand 19 holds the substrate W by clamping the substrate W by the three guides 67, the control unit CU calculates the center position of the substrate W on the basis of the movement distance of the guide 67 at that time and stores the center position in the clamping information storage unit 95. The center position, which is stored in the clamping information storage unit 95, of the substrate W when the substrate W is clamped is generally shifted from the center position of the designed substrate W in the first hand 19. The clamping information that is the center position of the substrate W stored in the clamping information storage unit 95 is referred to by the control unit CU, and the control unit CU operates the indexer robot IR so as to correct the center position when placing the substrate W on the delivery part 15, and delivers the substrate W to the delivery part 15.

A dummy substrate position information storage unit 96 stores the position information acquired from the encoder 81, for example, in a case where the dummy substrate DW described above is clamped by the first hand 19. Specifically, the dummy substrate position information storage unit 96 stores the position information acquired from the encoder 81 at the timing when the tactile sensor 73 detects that the guide 67 abuts on the outer peripheral surface of the substrate W. The dummy substrate position information storage unit 96 is divided into a guide 67 of the right finger portion 61, a guide 67 of the left finger portion 61, and a guide 67 of the pusher 87 in the width direction Y to store the position information. The position information includes initial position information P0 and periodic position information P1 and P2 to be described later. The position information is stored in association with the date when the dummy substrate DW is clamped.

In a case where the guide 67 is replaced with a new guide 67, the dummy substrate DW is clamped by the new guide 67. In a case where the guide 67 is replaced, the control unit CU may perform control to access the dummy substrate placement part 30 and clamp the dummy substrate DW. Such control may be performed by the control unit CU by an operator operating an operation unit provided outside the substrate processing apparatus 1.

If the guide 67 is replaced with a new guide 67, the date in a case where the guide 67 is replaced is stored. In a case where the dummy substrate DW is clamped by the replaced guide 67, the position information acquired from the encoder 81 is stored in the dummy substrate position information storage unit 96 as the position information (hereinafter, referred to as initial position information) in the initial state of the guide 67.

The control unit CU periodically performs control to clamp the dummy substrate DW by the guide 67 on the basis of the date on which the guide 67 has been replaced. The dummy substrate position information storage unit 96 also stores position information (hereinafter, referred to as periodic position information) acquired from the encoder 81 by periodic clamping of the dummy substrate DW. In addition, a process of acquiring the periodic position information is referred to as periodic measurement.

As a result, it is possible to record a process in which the guide 67 consumes from the initial state.

Every time the periodic position information is acquired, a differential position information storage unit 97 acquires a difference between the initial position information and the periodic position information. For example, the control unit CU obtains the movement distance of the guide 67 in the initial state on the basis of the initial position information. The control unit CU obtains the movement distance of the guide 67 at the time of periodic measurement on the basis of the periodic position information. The control unit CU obtains a difference in the movement distance of the guide 67 between the initial state and the time of periodic measurement. The differential position information storage unit 97 stores the difference in the movement distance as differential position information. The differential position information is a value indicating the consumption of the guide 67.

A threshold information storage unit 98 stores the consumption degree of the guide 67 serving as an index for replacing the guide 67. The consumption degree of the guide 67 is threshold information for determining whether to notify that the guide 67 needs to be replaced on the basis of the differential position information. That is, first threshold information is a numerical value of the differential position information for which the guide 67 needs to be replaced. Second threshold information is a numerical value of the differential position information for which the guide 67 needs to be replaced immediately.

A notification control unit 111 performs, for example, two-stage notification in accordance with an instruction from the control unit CU. That is, the control unit CU performs first control in a case where the differential position information at the time of the periodic measurement is equal to or more than a first threshold and less than a second threshold. The first control is, for example, control for causing the notification control unit 111 to issue a first warning. The first warning is a warning indicating that the guide 67 needs to be replaced. Specifically, for example, a message such as “replace guide (first warning)” is displayed on an image display unit 113 provided in the substrate processing apparatus 1. Instead of displaying the message, a first lamp indicating that the guide 67 needs to be replaced may be turned on.

The notification control unit 111 stores the position information acquired from the encoder 81. The dummy substrate position information storage unit 96 issues the first warning when the differential position information of any one of the guide 67 of the right finger portion 61, the guide 67 of the left finger portion 61, and the guide 67 of the pusher 87 in the width direction Y exceeds the first threshold.

The control unit CU performs second control in a case where the differential position information at the time of the periodic observation performed after the differential position information exceeds the first threshold is equal to or more than the second threshold. The second control is, for example, control for causing the notification control unit 111 to issue a second warning. The second warning is to display a message such as “replace guide immediately (second warning)” on the image display unit 113. Instead of displaying the message, a second lamp indicating that replacement of the guide 67 is immediately necessary may be turned on. Instead of the second warning or together with the second warning, the control unit CU may control the indexer robot IR not to transfer the substrate W until the guide 67 is replaced.

The control system of the indexer robot IR described above also includes a center robot CR. That is, the control system of the center robot CR includes the clamping control unit 97. Similarly to the indexer robot IR, in the center robot CR, in a case where the substrate W is clamped by the three guides 67, the center position of the substrate W is calculated, and the calculated center position is stored in the clamping information storage unit 95. The control unit CU refers to the center position of the substrate W stored in the clamping information storage unit 95, and operates the center robot CR in order to deliver the substrate W to and from each processing unit 31.

The control using the dummy substrate DW described above is also performed on the center robot CR.

### <9. Operation Flow>

A transfer operation of the substrate W by the indexer robot IR in the substrate processing apparatus 1 will be described with reference to FIGS. 12 to 22. FIG. 12 is a flowchart for explaining an operation related to transfer. FIGS. 13, 15, 17, 19, 21, and 22 are schematic views for explaining the operation in side view. FIGS. 14, 16, 18, and 20 are schematic views for explaining the operation in plan view.

In the following description, an operation of receiving the substrate W from the carrier C will be described as an example.

### Step S1

Shape information of the substrate W is acquired. When the lid CL is detached from the carrier C by the detachable unit 43, the control unit CU acquires the shape information of each substrate W by the substrate sensor 45. The control unit CU stores the acquired shape information in the shape information storage unit 93 in association with each substrate W.

### Step S2

Clamping information corresponding to shape information is acquired. The control unit CU reads the clamping information corresponding to the shape information of the substrate W received by the first hand 19 from the clamping information storage unit 95.

### Step S3

As illustrated in FIGS. 13 and 14, the control unit CU operates the horizontal drive mechanism 57 of the indexer robot IR to cause the first hand 19 to enter the delivery position in the carrier C. Since the first hand 19 is a lower holding hand that receives the substrate W so as to lift the substrate W from below, the first hand 19 enters below the position where the substrate W to be received is placed. At this time, the control unit CU preferably expands the three guides 67 of the first hand 19 to the maximum. In other words, the guide 67 of the finger portion 61 is moved to the front side X to the maximum, and the guide 67 of the pusher 87 is moved to the rear side X to the maximum. As a result, even if the placement position of the substrate W is greatly shifted, the substrate W can be reliably received by the first hand 19.

### Step S4

As illustrated in FIGS. 15 and 16, the control unit CU moves the substrate W so that the substrate W can be clamped by the first hand 19. Specifically, the control unit CU operates the indexer robot IR to raise the first hand 19 in the vertical direction Z so that the substrate W is positioned below the upper end of the guide 67 and above the upper surface of the finger portion 61.

### Step S5

As illustrated in FIGS. 17 and 18, the control unit CU operates the clamping control unit 97 to move the three guides 67 of the first hand 19 toward the outer peripheral surface of the substrate W.

### Step S6

The control unit CU branches the processing depending on whether each guide 67 abuts on the outer peripheral surface of the substrate W. Step S5 is repeated until each guide 67 abuts on the outer peripheral surface of the substrate W. In other words, the movement of each guide 67 toward the outer peripheral surface of the substrate W is maintained until each guide 67 abuts on the outer peripheral surface of the substrate W. Whether the substrate W abuts on the outer peripheral surface of the substrate W is determined by a signal of the tactile sensor 73.

### Step S7

In a case where each guide 67 abuts on the outer peripheral surface of the substrate W, the following operation is performed. As illustrated in FIGS. 19 and 20, the control unit CU applies a biasing force (indicated by a white arrow in the drawing) to the guide 67 according to the clamping information.

Specifically, the control unit CU refers to the clamping information storage unit 95 and reads clamping information corresponding to the substrate W. The control unit CU operates the clamping control unit 97 according to the read clamping information to bias the guide 67. As a result, the guide 67 is pressed against the outer peripheral surface of the substrate W. Since each guide 67 is biased on the basis of the clamping information, the substrate W can be supported by each guide 67 so that the substrate W does not fall on the finger portion 61. In addition, since each guide 67 is biased on the basis of the clamping information, it is possible to suppress the occurrence of damage in the substrate W and the guide 67.

### Step S8

As illustrated in FIG. 21, the control unit CU operates the indexer robot IR to move the first hand 19 in the vertical direction Z by a predetermined distance.

Next, as illustrated in FIG. 22, the control unit CU operates the horizontal drive mechanism 57 of the indexer robot IR to move the first hand 19 out of the delivery position of the carrier C. Note that the above-described biasing force (indicated by a white arrow in the drawing) is maintained until the substrate W is transferred to the transfer destination.

### <10. Consumption Degree of Guide>

FIG. 23 to FIGS. 25A to 25C will be referred to. FIG. 23 is a plan view of the hand for explaining the first consumption degree of the guide. FIG. 24 is a plan view of the hand for explaining the second consumption degree of the guide. FIGS. 25A to 25C are side views of the hand for explaining the first and second consumption degrees of the guide. Note that the illustrated consumption of the guide 67 is enlarged from the actual consumption for convenience of illustration.

FIG. 23 and FIGS. 25A to 25C will be referred to. The guide 67 indicated by a broken line in FIG. 23 indicates a state in which the outer peripheral surface of the dummy substrate DW is not clamped. The guide 67 indicated by a broken line is not horizontally driven. FIG. 23 illustrates the guide 67 indicated by a two-dot chain line on the center side of the dummy substrate DW with respect to the guide 67 indicated by a broken line. As also illustrated in FIG. 25A, the guide 67 indicated by a two-dot chain line indicates a state of clamping the outer peripheral surface of the dummy substrate DW. The guide 67 indicated by a two-dot chain line is horizontally driven from the position of the guide 67 indicated by a broken line. The guide 67 indicated by a two-dot chain line indicates a new guide 67, that is, a guide 67 that has not worn.

FIG. 23 illustrates a guide 67 indicated by a solid line on the center side of the dummy substrate DW with respect to the guide 67 indicated by a two-dot chain line. The guide 67 indicated by a solid line indicates a state of clamping the outer peripheral surface of the dummy substrate DW. Unlike the guide 67 indicated by a two-dot chain line, the guide 67 indicated by a solid line is used for a predetermined period, and as a result, a hatched first consumption F1 occurs. The first consumption F1 occurs in any of the three guides 67. The first consumption F1 is, for example, wear. As illustrated in FIG. 25B, the wear occurs on the outer peripheral surface of the guide 67 by repeating the clamping of the substrate W by the guide 67 for a predetermined period. The guide 67 indicated by a solid line indicates a state in which the outer peripheral surface of the dummy substrate DW is clamped by the deepest surface of the portion where the first consumption F1 has occurred. The first consumption F1 corresponds to the first consumption degree indicating the consumption degree of the guide 67. The first consumption F1 may be damage of the guide 67. The damage occurs, for example, when the guide 67 clamps the substrate W to be processed by the processing unit 31, the outer peripheral surface of the guide 67 is scraped by the edge (sharp edge) of the substrate W.

FIG. 24 and FIGS. 25A to 25C will be referred to. In FIG. 24, similarly to FIG. 23, a guide 67 indicated by a broken line and a guide 67 indicated by a two-dot chain line are illustrated. The guide 67 indicated by a solid line indicates a state in which the guide 67 in which a second consumption F2 more greatly consumed than the first consumption F1 has occurred clamps the outer peripheral surface of the dummy substrate DW. As illustrated in FIG. 25C, the second consumption F2 is wear caused by further repeating the clamping of the substrate W by the guide 67 for a predetermined period from the time point at which the first consumption F1 illustrated in FIG. 25B has occurred. The guide 67 indicated by a solid line indicates a state in which the outer peripheral surface of the dummy substrate DW is clamped by the deepest surface of the portion where the second consumption F2 has occurred. The second consumption F2 corresponds to the second consumption degree indicating the consumption degree of the guide 67. The second consumption F2 occurs in any of the three guides 67.

A point P illustrated in FIGS. 23 and 24 is the center of the guide 67 indicated by a broken line in a state where the guide 67 does not clamp the outer peripheral surface of the dummy substrate DW. A point P0 illustrated in FIGS. 23, 24, and 25A to 25C is the center of the guide 67 indicated by a two-dot chain line in a state where the guide 67 that has not worn clamps the outer peripheral surface of the dummy substrate DW. The point P0 is the initial position information described above. The point P0 is also referred to as an initial position P0 or initial position information P0. The initial position information P0 is position information when the center of the guide 67 is moved from the point P to the point P0. The initial position information P0 is a distance from the point P to the point P0.

A point P1 illustrated in FIGS. 23 and 25A to 25C is the center of the guide 67 indicated by a solid line in a state where the guide 67 in which the first consumption F1 has occurred clamps the outer peripheral surface of the dummy substrate DW. A point P2 illustrated in FIGS. 24 and 25A to 25C is the center of the guide 67 indicated by a solid line in a state where the guide 67 in which the second consumption F2 has occurred clamps the outer peripheral surface of the dummy substrate DW. The points P1 and P2 are the above-described periodic position information acquired when the dummy substrate DW is periodically clamped by the guide 67. The points P1 and P2 are also referred to as periodic positions P1 and P2 or periodic position information P1 and P2. The periodic position information P1 and P2 is position information when the center of the guide 67 is moved from the point P to the points P1 and P2. The periodic position information P1 and P2 are distances from the point P0 to the point P1. Note that the point P0, the point P1, and the point P2 are set at the center of the guide 67, but may be set at the front end or the rear end of the guide 67.

A distance L1 between the initial position P0 and the periodic position P1 illustrated in FIGS. 23 and 25A to 25C is the above-described differential position information. The distance L1 is also referred to as differential position information L1. The differential position information L1 is a difference between the above-described periodic position information P1 and the initial position information P0. That is, the control unit CU calculates a difference between the initial position information P0 of the guide 67 in the initial state and the acquired periodic position information P1 of the guide 67 as the differential position information L1. A distance L2 between the initial position P0 and the periodic position P2 illustrated in FIGS. 24 and 25A to 25C is the above-described differential position information. The distance L2 is also referred to as differential position information L2. The differential position information L2 is a difference between the above-described periodic position information P2 and the initial position information P0. That is, the control unit CU calculates a difference between the initial position information P0 of the guide 67 in the initial state and the acquired periodic position information P2 of the guide 67 as the differential position information L2.

<11. Determination of Consumption Degree and Control according to Consumption Degree>

FIGS. 26A and 26B will be referred to. FIG. 26A is a graph illustrating the relationship between the consumption degree of the guide provided in the indexer robot IR and the elapsed period, and FIG. 26B is a graph illustrating the relationship between the consumption degree of the guide provided in the center robot CR and the elapsed period.

The differential position information L indicated in FIG. 26A is a difference between the initial position information and the periodic position information acquired by the guide 67 of the indexer robot IR periodically clamping the dummy substrate DW. The differential position information L may be any one of the guides 67 of the two finger portions 61 and the guide 67 of one pusher 87, or may be two or more pieces.

The differential position information L is represented by a length. The elapsed period indicates an interval at which the dummy substrate DW is periodically clamped. The interval is, for example, one month. The start of the elapsed period is when the guide 67 is replaced with a new guide 67. The differential position information L1 is a value set as the first threshold by the control unit CU. The first threshold corresponds to the first consumption F1 and the first consumption degree described above. The first threshold is a value for the control unit CU to issue the first warning indicating that the guide 67 needs to be replaced. The differential position information L2 is a value set by the control unit CU as a second threshold higher than the first threshold. The second threshold corresponds to the second consumption F2 and the second consumption degree described above. The second threshold is a value for the control unit CU to issue the second warning indicating that the guide 67 needs to be replaced immediately, or for not allowing the indexer robot IR to transfer the substrate W until the guide 67 is replaced.

Specifically, for example, the differential position information L of the guide 67 of the indexer robot IR does not exceed the differential position information L1 (first threshold) until the sixth month from the start of the elapsed period. That is, the control unit CU determines that the consumption degree of the guide 67 does not exceed the first threshold and the first consumption degree on the basis of the acquired differential position information L. At the seventh month from the start of the elapsed period, the differential position information L of the guide 67 of the indexer robot IR exceeds the differential position information L1 (first threshold). That is, the control unit CU determines that the consumption degree of the guide 67 exceeds the first threshold and the first consumption degree on the basis of the acquired differential position information L. At this time, the control unit CU performs first control for replacing the guide 67. In the first control, for example, the first warning indicating that the guide 67 needs to be replaced is issued. The operator who sees the first warning replaces the three guides 67. That is, in a case where the differential position information L of one 67 among the three guides 67 exceeds the first threshold, the first control is performed.

When the first threshold is exceeded, the transfer of the substrate W is not hindered unless the guide 67 is immediately replaced. Therefore, it is also possible to continue to use the guide 67 for a while without replacing the guide 67 when the first threshold is exceeded. Thereafter, the differential position information L does not exceed the second differential position information L2 (second threshold) until the tenth month from the start of the elapsed period. That is, the control unit CU determines that the consumption degree of the guide 67 does not exceed the second threshold and the second consumption degree on the basis of the acquired differential position information L. At the eleventh month from the start of the elapsed period, the differential position information L exceeds the second differential position information L2 (second threshold). That is, the control unit CU determines that the consumption degree of the guide 67 exceeds the second threshold and the second consumption degree on the basis of the acquired differential position information L. At this time, the control unit CU performs second control for replacing the guide 67. For example, the second warning is issued to more strongly urge the operator than the first warning that it is necessary to replace the guide 67. In addition, control is performed such that the transfer of the substrate W by the indexer robot IR is not permitted until the guide 67 is replaced. As a result, it is possible to prevent the guide 67 that has been worn to such an extent as to hinder the transfer of the substrate W from being continuously used.

FIG. 26B is a graph illustrating the differential position information L acquired by the center robot CR. In the substrate processing apparatus 1 of the first embodiment, the center robot CR clamps the substrate W more frequently than the indexer robot IR. Therefore, the consumption speed of the guide 67 of the center robot CR is faster than that of the guide 67 of the indexer robot IR. In consideration of the consumption speed of the guide 67 in the center robot CR, the acquisition interval of the differential position information L in the center robot CR may be shorter than the acquisition interval of the differential position information L in the indexer robot IR.

The differential position information L indicated in FIG. 26B is a difference between the initial position information and the periodic position information acquired by the guide 67 of the center robot CT periodically clamping the dummy substrate DW. The differential position information L1 corresponding to the first threshold and the differential position information L2 corresponding to the second threshold may be the same value or different values between the indexer robot IR and the center robot CR.

Specifically, the differential position information L of the guide 67 of the center robot CR exceeds the first differential position information L1 (first threshold) at the fourth month from the start of the elapsed period. That is, the control unit CU determines that the consumption degree of the guide 67 of the center robot CR exceeds the first threshold and the first consumption degree on the basis of the acquired differential position information L. At this time, the control unit CU issues, for example, the above-described first warning as the first control for replacing the guide 67. The differential position information L of the guide 67 of the center robot CR exceeds the second differential position information L2 (second threshold) at the eleventh month from the start of the elapsed period. That is, the control unit CU determines that the consumption degree of the guide 67 of the center robot CR exceeds the second threshold and the second consumption degree on the basis of the acquired differential position information L. At this time, as the second control for immediately replacing the guide 67, the control unit CU issues, for example, the above-described second warning or performs the above-described control for not permitting the transfer of the substrate W. As a result, it is possible to prevent not only the indexer robot IR but also the center robot CR from continuing to use the guide 67 that has been consumed so much as to hinder the transfer of the substrate W.

As described above, the indexer robot IR and the center robot CR according to the first embodiment, and the substrate processing apparatus 1 including these robots include the tactile sensor 73 and the encoder 81 that acquire the initial position information P0 and the periodic position information P1 and P2 indicating the positions in the horizontal plane where the guides 67 clamp the outer peripheral surface of the substrate W, and the control unit CU that determines the consumption degree of the guide 67 on the basis of the acquired initial position information P0 and periodic position information P1 and P2. The periodic position information P1 and P2 changes depending on the consumption degree of the guide 67. By determining the consumption degree of the guide 67, it is possible to make it difficult to cause transfer failure of the substrate W due to consumption of the guide 67.

In addition, the control unit CU of the first embodiment calculates differential position information L which is a difference between the initial position information P0 of the guide 67 in the initial state and the acquired periodic position information P1 and P2 of the guide 67, and determines the consumption degree of the guide 67 on the basis of the differential position information L. As a result, by comparing the initial position information P0 of the guide 67 in the initial state with the acquired periodic position information P1 and P2 of the guide 67, the consumption degree of the guide 67 can be accurately detected.

Furthermore, in a case where the differential position information L exceeds the first threshold (first consumption degree), the control unit CU of the first embodiment issues, for example, the first warning indicating that the guide 67 needs to be replaced. As a result, in a case where the consumption degree of the guide 67 becomes such that the differential position information L exceeds the first threshold (first consumption degree), it is possible to appropriately notify that the guide 67 needs to be replaced.

In addition, in a case where the differential position information L exceeds the second threshold (second consumption degree) having a consumption degree larger than the first threshold (first consumption degree), the control unit CU of the first embodiment issues, for example, the second warning more strongly urging the operator than the first warning that it is necessary to replace the guide 67. Instead of the second warning or together with the second warning, control is performed such that the transfer of the substrate W by the indexer robot IR (or the center robot CR) is not permitted until the guide 67 is replaced. As a result, in a case where the differential position information L has a large consumption degree of the guide exceeding the second threshold (second consumption degree), it is possible to prevent the guide 67 that has been worn to such an extent as to hinder the transfer of the substrate W from being continuously used.

Further, in the first embodiment, a servomotor 79 that applies a driving force for driving the guide 67 to move forward and backward, and an encoder 81 that detects the rotation of the servomotor 79 and outputs the rotation of the servomotor 79 as a detection signal at a timing when the tactile sensor 73 detects that the guide 67 abuts on the outer peripheral surface of the substrate W are included, and the control unit CU acquires the initial position information P0 and the periodic position information P1 and P2 on the basis of the detection signal applied by the servomotor 79. As a result, the consumption degree can be suitably determined using the output from the encoder 81 that detects the rotation of the servomotor 79 at the timing when the tactile sensor 73 detects that the guide 67 abuts on the outer peripheral surface of the substrate W.

Furthermore, the control unit CU of the first embodiment causes the image display unit 113 that outputs information to output information such as the first warning and the second warning according to the consumption degree of the guide 67 according to the consumption degree of the guide 67. As a result, the operator can recognize the consumption degree of the guide 67.

In addition, the control unit of the first embodiment stops the transfer of the substrate W according to the consumption degree of the guide 67. As a result, transfer failure of the substrate W can be prevented in advance.

In the first embodiment, the substrate W clamped by the guide 67 when the initial position information P0 and the periodic position information P1 and P2 are acquired is the dummy substrate DW that is not processed by the processing unit 31. As a result, the consumption degree of the guide 67 can be determined without being affected by the difference in the shape of the substrate W.

In addition, in the first embodiment, the dummy substrate DW is placed in the substrate processing apparatus 1 in advance, and the consumption degree of the guide 67 is determined at a preset cycle. As a result, the consumption degree of the guide 67 can be determined periodically in the substrate processing apparatus 1.

The correspondence between the above-described first embodiment and the configuration of the present invention is as follows.

At least one of the indexer robot IR and the center robot CR corresponds to a “substrate transfer apparatus” and a “transfer robot” in the present invention. The dummy substrate DW corresponds to a “substrate” in the present invention. Each guide 67 corresponds to a “movable guide” in the present invention. The movable piece 71, the servomotor 79, and the ball screw 83 correspond to an “advancing/retracting drive mechanism” in the present invention. The tactile sensor 73, the encoder 81, and the control unit CU that receives the timing and the position detection signal at which the guide 67 abuts on the dummy substrate DW from the tactile sensor 73 and the encoder 81 correspond to the “acquisition unit” in the present invention. The initial position information P0 and the periodic position information P1 and P2 correspond to “clamp position information” of the present invention. The control unit CU corresponds to a “control unit” in the present invention. The first threshold (first consumption degree) and the second threshold (second consumption degree) correspond to the “consumption degree” in the present invention. The differential position information L, the differential position information L1, and the differential position information L2 correspond to “differential information” in the present invention. The image display unit 113 corresponds to an “output unit” in the present invention. The clamping control unit 97 and the control unit CU correspond to a “control unit” in the present invention. The processing unit 31 and the rear surface cleaning unit SSR correspond to a “processing unit” in the present invention. The placing table 13 corresponds to a “carrier placement part” in the present invention. The delivery part 15 corresponds to a “temporary placement part” in the present invention.

The present invention is not limited to the above embodiment, and can be modified as follows.
(1) In the first embodiment described above, the dummy substrate DW is placed in the dummy substrate placement part 30 of the substrate processing apparatus 1 in advance. However, the dummy substrate DW may be placed in the carrier C. Specifically, the carrier C containing the dummy substrate DW is placed on the placing table 13 immediately after the replacement of the guide 67 and at a predetermined periodic measurement timing thereafter. When the dummy substrate DW is unloaded from the carrier C, the indexer robot IR clamps the dummy substrate DW with the guide 67. The indexer robot IR transfers the dummy substrate DW from the carrier C to the delivery part 15. The center robot CR clamps the dummy substrate DW with the guide 67 when unloading the dummy substrate DW from the delivery part 15. The indexer robot IR may be configured to clamp the dummy substrate DW placed in the carrier C, and the center robot CR may be configured to hold the dummy substrate DW placed in the dummy substrate placement part 30.
(2) In the first embodiment described above, the differential position information L of each of the guide 67 of the right finger portion 61, the guide 67 of the left finger portion 61, and the guide 67 of the pusher 87 in the width direction Y is acquired. However, the differential position information L of any one of the guides 67 may be acquired.
(3) In the first embodiment described above, the dummy substrate position information storage unit 96 stores the position information acquired from the encoder 81. The notification control unit 111 issues the first warning when the differential position information of any one 67 of the guide 67 of the right finger portion 61, the guide 67 of the left finger portion 61, and the guide 67 of the pusher 87 in the width direction Y exceeds the first threshold. However, the present invention is not limited to such a configuration. The first warning may be issued in a case where the differential position information of the two guides 67 out of the three guides 67 exceeds the first threshold. In a case where the differential position information of the three guides 67 exceeds the first threshold, the first warning may be issued. The same applies to the second threshold.
(4) In the first embodiment described above, the position where the contact of the guide 67 with the outer peripheral surface of the dummy substrate DW is detected by the tactile sensor 73 is treated as the position where the dummy substrate DW is clamped by the guide 67. However, the contact of the guide 67 with the outer peripheral surface of the dummy substrate DW may be detected by a sensor other than the tactile sensor 73.
(5) In the first embodiment described above, the position information of the guide 67 is acquired on the basis of the position information acquired from the encoder 81 connected to the servomotor 79. However, the present invention is not limited to such a configuration. For example, the position information may be acquired from the movement amount of the movable piece 71 by connecting a linear scale (linear encoder) to the movable piece 71 connected to the ball screw 83. The control unit CU that measures the position of the guide 67 on the basis of the measurement signals from the linear scale (linear encoder) and the linear scale (linear encoder) corresponds to the “sensor” and the “measurement unit” in the present invention.
(6) In the first embodiment described above, the tactile sensor 73 is employed. However, the present invention is not limited to such a configuration. That is, as long as it can be detected that the guide 67 abuts on the outer peripheral surface of the substrate W, another detector may be adopted. As the outer peripheral surface detector, for example, a proximity sensor, a reflective sensor, or the like may be adopted.
(7) In the first embodiment described above, the tactile sensor 73 is provided at a portion where the hand 67 is attached to the finger portion 61. However, the present invention is not limited to such an embodiment. That is, the tactile sensor 73 may be provided on the side surface of the guide 67. In this case, the detection surface 75 is preferably directed toward the outer peripheral surface side of the substrate W. This is because the detection sensitivity of the tactile sensor 73 can be increased.
(8) In the first embodiment described above, the guide 67 has a columnar shape, but the present invention is not limited to such an embodiment. That is, the shape of the guide 67 is not limited.
(9) In the first embodiment described above, the first hand 19 of the indexer robot IR has been described as an example. However, the present invention can also be applied to the second hand 21 of the indexer robot IR and the first hand 33 and the second hand 35 of the center robot CR.
(10) In the first embodiment described above, a configuration in which all the three guides 67 are movable is adopted. However, the present invention is not limited to such a configuration. That is, the present invention may be configured such that at least one guide 67 is movable.
(11) In the first embodiment described above, a configuration including three guides 67 is adopted. However, the present invention is not limited to such a configuration. That is, the present invention may be configured to include at least two or four or more guides 67. For example, the first hand 19 including the two guides 67 may include one finger portion having an I shape in plan view, and may include one arc-shaped guide 67 corresponding to the outer edge shape of the substrate W on the distal end side and the pusher 87 on the proximal end side.
(12) In the first embodiment described above, the advancing/retracting drive mechanism is configured to move the guide 67 with the movable piece 71, the servomotor 79, and the ball screw 83. However, the present invention is not limited to such a configuration. For example, a configuration including a wire having one end side connected to a spring, a guide fixedly attached to a part of the wire, and a drive unit that winds the other end side of the wire to move the wire in the front-rear direction X may be adopted.
(13) In the first embodiment described above, the guide 67 is driven to advance and retract in the front-rear direction X with respect to the finger portion 61, but the present invention is not limited to such a configuration. For example, the guide 67 may be fixedly attached to the finger portion 61, and the finger portion 61 may be attached to the finger attachment section 65 so as to be movable forward and backward in the front-rear direction X in the finger attachment section 65. As a result, the movable portion can be disposed outside the outer peripheral surface of the substrate W, which is advantageous in terms of cleanliness.
(14) In the first embodiment described above, the tactile sensor 73 that detects that the guide 67 abuts on the outer peripheral surface of the substrate W is provided. However, the present invention does not essentially require the tactile sensor 73. That is, when the guide 67 of the pusher 87 is moved toward the outer peripheral surface of the substrate W by the servomotor 79, the control unit CU may adjust the biasing force to the substrate W by the guide 67 according to the shape of the substrate W regardless of the position of the outer peripheral surface. In a case where the diameter of the substrate W to be processed is known, the position of the outer peripheral surface of the substrate W is almost known, and thus, the control unit CU can adjust the biasing force to the substrate W by the guide 67 according to the position information from the encoder 81. Note that, as in the first embodiment described above, the time until the substrate W is held can be shortened by adjusting the biasing force after detecting the outer peripheral surface of the substrate W using the tactile sensor 73.

### Second Embodiment

Next, a second embodiment of the present invention will be described with reference to the drawings.

In the first embodiment described above, the position information acquired from the encoder 81 at the timing when the tactile sensor 73 detects that the guide 67 abuts on the outer peripheral surface of the dummy substrate DW is treated as the position information in which the dummy substrate DW is clamped by the guide 67. The second embodiment is different from the first embodiment in that the position information in which the guide 67 abuts on the outer peripheral surface of the dummy substrate DW is acquired directly from the position information acquired from the encoder 81.

FIG. 27 is a side view of the hand in the substrate processing apparatus according to the second embodiment. Note that the configuration and the like of the substrate processing apparatus 1 are similar to those of the first embodiment described above. Therefore, a detailed description of the substrate processing apparatus 1 will be omitted.

In the following, similarly to the first embodiment described above, the configuration of the first hand 19 included in the indexer robot IR will be described as an example. The hand according to the second embodiment is indicated by a first hand 19A.

### <1. Details of Hand>

The first hand 19A includes two finger portions 61 and one palm portion 59. Each of the two finger portions 61 includes a guide 67. One palm portion 59 includes one guide 67. The first hand 19A includes three guides 67.

The three guides 67 move in the front-rear direction X with a configuration similar to that of the first embodiment described above. That is, the guide 67 is moved by the movable piece 71, the lateral hole 77, the servomotor 79, and the ball screw 83. However, the first hand 19 in the second embodiment does not include the tactile sensor 73.

### <2. Control System>

A control system will be described with reference to FIG. 28. FIG. 28 is a block diagram illustrating a control system in a substrate processing apparatus according to the second embodiment.

The same reference numerals as those of the above-described first embodiment are given to the configurations common to the above-described first embodiment, and a detailed description thereof will be omitted.

The control unit CU operates the indexer robot IR. In particular, the operation of clamping the substrate W by the first hand 19 is operated via a clamping control unit 97A.

The clamping control unit 97A is connected to the servomotor 79 and the encoder 81. The clamping control unit 97A operates the servomotor 79 on the basis of an instruction from the control unit CU to move the three guides 67. At that time, the clamping control unit 97A operates the servomotor 79 according to the position information from the encoder 81. The clamping control unit 97A can detect the drive current supplied to the servomotor 79 as drive current information. The clamping control unit 97A determines that the guide 67 abuts on the outer peripheral surface of the substrate W on the basis of one or both of the position information and the drive current information.

That is, when the guide 67 abuts on the outer peripheral surface of the substrate W, the movement of the guide 67 is temporarily hindered. Therefore, the displacement of the position information from the encoder 81 temporarily stops. Even if the guide 67 abuts on the outer peripheral edge of the substrate, it is necessary to increase the torque of the servomotor 79 in order to further move the guide 67 toward the outer peripheral surface of the substrate W. Therefore, the drive current to the servomotor 79 increases, and the drive current information is displaced. Therefore, by monitoring one or both of the position information and the drive current information, it is possible to accurately determine that the guide 67 abuts on the outer peripheral surface of the substrate W. After the guide 67 abuts on the outer peripheral surface of the substrate W, the clamping control unit 97A adjusts the biasing force of the guide 67 to the outer peripheral surface of the substrate W according to the shape information from the shape information storage unit 93 and clamps the substrate W.

A dummy substrate position information storage unit 96 stores the position information acquired from the encoder 81, for example, in a case where the dummy substrate DW described above is clamped by the first hand 19. Specifically, the dummy substrate position information storage unit 96 stores the position information acquired from the encoder 81 at the timing when the displacement of the position information from the encoder 81 temporarily stops. That is, at the timing when the displacement of the position information from the encoder 81 temporarily stops, the position information acquired from the encoder 81 is stored as the position information in which the guide 67 abuts on the outer peripheral surface of the substrate W, that is, the position information in which the guide 67 clamps the outer peripheral surface of the substrate W.

The correspondence between the above-described second embodiment and the present invention is as follows.

The encoder 81 and the dummy substrate position information storage unit 96 correspond to an “acquisition unit” in the present invention.

According to the second embodiment, the control unit CU determines that the guide 67 abuts on the outer peripheral surface of the substrate W on the basis of at least one of the drive current information from the clamping control unit 97A and the position information from the encoder 81. Therefore, it is not necessary to provide the tactile sensor 73 or the like to detect whether the guide 67 abuts on the outer peripheral surface of the substrate W. As a result, the structure can be simplified, and the cost can be suppressed.

The present invention is not limited to the above embodiment, and can be modified as follows.

In the second embodiment described above, (1) to (5) and (8) to (14) other than (6) and (7) in the modification of the first embodiment may be adopted. In addition, similarly to (14) in the modification of the first embodiment, the biasing force to the substrate W may be adjusted without detecting that the guide 67 abuts on the outer peripheral surface of the substrate W.

### Third Embodiment

Next, a third embodiment of the present invention will be described with reference to the drawings.

The guide 67 of the right finger portion 61, the guide 67 of the left finger portion 61, and the guide 67 of the pusher 87 are all movable in the width direction Y, and the control unit CU determines whether the differential position information of any one of the guides 67 exceeds a threshold. The third embodiment is different from the first embodiment in that the number of movable guides 67 is one, and the control unit CU determines whether the differential position information of one guide 67 exceeds a threshold.

FIG. 29 is a plan view of a hand in the substrate processing apparatus according to the third embodiment. FIG. 30 is a view in the direction of arrow 100-100 in FIG. 29. Note that the configuration and the like of the substrate processing apparatus 1 are similar to those of the first embodiment described above, and thus detailed description thereof will be omitted.

In the following, similarly to the first and second embodiments described above, the configuration of the first hand 19 included in the indexer robot IR will be described as an example. The hand according to the third embodiment is indicated by a first hand 19B.

### <1. Details of Hand>

The first hand 19B is different from the first and second embodiments in the configuration of the finger portion 61. That is, the finger portions 61 include guides 67A on both end portions of the front side X and the rear side X, respectively. Each guide 67A is a fixed type that is not movable. Each guide 67A does not move in the front-rear direction X in the finger portion 61.

The guide 67A includes an inclined surface 101 and a clamping portion 103. The inclined surface 101 is formed so as to be lowered toward the center side of the substrate W. In other words, the inclined surface 101 is formed so as to be higher outward than the outer peripheral surface of the substrate W. The clamping portion 103 is erected along the outer peripheral surface of the substrate W. The clamping portion 103 is preferably formed such that a portion facing the outer peripheral surface of the substrate W in plan view has the same shape as the shape of the corresponding outer peripheral surface of the substrate W. This is because the substrate W can be stably held although the contact area increases. The four guides 67A are disposed slightly outside the outer shape of the substrate W in plan view.

The guide 67A is attached to the upper surface of the finger portion 61 via the tactile sensor 73. The tactile sensor 73 is attached to the guide 67A such that the force applied to the guide 67A is transmitted to the detection surface 75.

In the first hand 19B described above, after the substrate W is placed in the inclined surface 101 of the guide 67A, the outer peripheral surface of the substrate W is urged to the front side X by the guide 67 of the pusher 87. As a result, the outer peripheral surface of the substrate W located in the front side X slides up the inclined surface 101, is pressed by the clamping portion 103, and is clamped between the guide 67 of the pusher 87 and the two guides 67A. As a result, the substrate W is held by the first hand 19.

The tactile sensor 73 of the guide 67A detects that the substrate W is placed. That is, the tactile sensor 73 only needs to detect the force in the vertical direction Z. The signal from the tactile sensor 73 of the guide 67A is used by the clamping control unit 97 to determine whether the substrate W is present. In a case where the clamping control unit 97 determines that there is no substrate W, the determination is transmitted to the control unit CU. Furthermore, the clamping control unit 97 can determine the placement posture of the substrate W from the state of application of the force in the four guides 67A. In a case where the inclination is large, it may be determined that there is no substrate W since there is an adverse effect during transfer of the substrate W.

### <2. Consumption Degree of Guide>

FIGS. 31 and 32 will be referred to. FIG. 31 is a plan view of the hand for explaining the first consumption degree of the guide. FIG. 32 is a plan view of the hand for explaining the second consumption degree of the guide. FIGS. 33A to 33C are side views of the hand for explaining the first and second consumption degrees of the guide.

FIGS. 31 and 33A to 33C will be referred to. In FIG. 31, similarly to the first embodiment, a guide 67 of the pusher 87 indicated by a broken line and a guide 67 of the pusher 87 indicated by a two-dot chain line are illustrated. As illustrated in FIG. 33A, the guide 67 of the pusher 87 indicated by a two-dot chain line indicates a state in which the outer peripheral surface of the dummy substrate DW is clamped between the guide 67 of the pusher 87 that is not worn and the two guides 67A on the distal end side. The guide 67 of the pusher 87 indicated by a solid line indicates a state in which the guide 67 of the pusher 87 in which the first consumption F1 has occurred and the two guides 67A on the distal end side clamp the outer peripheral surface of the dummy substrate DW. As illustrated in FIG. 33B, the first consumption F1 is wear caused by repeating the clamping of the substrate W by the guide 67 of the pusher 87 and the two guides 67A on the distal end side for a predetermined period of time. The guide 67 of the pusher 87 indicated by a solid line and the two guides 67A on the distal end side indicate a state in which the outer peripheral surface of the dummy substrate DW is clamped by the innermost surface of the portion where the first consumption F1 has occurred. The first consumption F1 corresponds to the first consumption degree indicating the consumption degree of the guide 67 of the pusher 87 and the two guides 67A on the distal end side.

FIGS. 32 and 33A to 33C will be referred to. In FIG. 31, similarly to the above description, a guide 67 of the pusher 87 indicated by a broken line and a guide 67 of the pusher 87 indicated by a two-dot chain line are illustrated. The guide 67 of the pusher 87 indicated by a solid line indicates a state in which the guide 67 of the pusher 87 in which the second consumption F2 has occurred and the two guides 67A on the distal end side clamp the outer peripheral surface of the dummy substrate DW. As illustrated in FIG. 33C, the second consumption F2 is wear caused by the guide 67 of the pusher 87 and the two guides 67A on the distal end side repeatedly clamping the substrate W from the time point when the first consumption F1 illustrated in FIG. 33B has occurred. The guide 67 of the pusher 87 indicated by a solid line and the two guides 67A on the distal end side indicate a state in which the outer peripheral surface of the dummy substrate DW is clamped by the innermost surface of the portion where the second consumption F2 has occurred. The second consumption F2 corresponds to the second consumption degree indicating the consumption degree of the guide 67 of the pusher 87 and the two guides 67A on the distal end side.

The points P0, P1, and P2 are position information of the guide 67 of the pusher 87. Similarly to the first embodiment, the point P0 is also referred to as an initial position P0 or initial position information P0. The points P1 and P2 are also referred to as periodic positions P1 and P2 or periodic position information P1 and P2.

The distance L1 between the initial position P0 and the periodic position P1 indicates a distance at which the guide 67 of the pusher 87 is pushed out more than the initial position P0 due to the first consumption F1 occurred in the guides 67A at the two positions on the distal end side and the guide 67 of the pusher 87. The distance L1 is the above-described differential position information. The distance L1 is also referred to as differential position information L1. The differential position information L1 is a difference between the above-described periodic position information P1 and the initial position information P0.

The distance L2 between the initial position P0 and the periodic position P2 indicates a distance at which the guide 67 of the pusher 87 is pushed out more than the initial position P0 due to the occurrence of the second consumption F2 in the guide 67A at the two positions on the distal end side and the guide 67 of the pusher 87. The distance L2 is the above-described differential position information. The distance L2 is also referred to as differential position information L2. The differential position information L2 is a difference between the above-described periodic position information P2 and the initial position information P0.

### <3. Control According to Consumption Degree>

Similarly to the first embodiment, when the differential position information L of the guide 67 of the pusher 87 exceeds a first threshold (differential position information L1), a first warning is issued as first control. The operator who has seen the first warning replaces the guide 67 of the pusher 87 and the two guides 67A on the distal end side. The two guides 67A on the proximal end side may also be replaced. In addition, when the differential position information L of the guide 67 of the pusher 87 exceeds the second threshold (differential position information L2), as the second control, the second warning and the control of not permitting the substrate W to be transferred until the guide 67 of the pusher 87 and the two guides 67A on the distal end side are replaced are performed.

As described above, in a case where only one guide 67 out of the plurality of guides 67 and 67A is movable, even with the configuration in which only the differential position information of the movable guide 67 is acquired without acquiring the differential position information of all the guides 67 and 67A, it is possible to prevent the guide 67 that has been consumed to such an extent that the transfer of the substrate W is hindered from being continuously used.

The correspondence between the above-described third embodiment and the configuration of the present invention is as follows. The guide 67 of the pusher 87 corresponds to a “movable guide” in the present invention.

The present invention is not limited to the above embodiment, and can be modified as follows.

In the third embodiment described above, (1), (5), (8), (9), (11), (12), and (14) other than (2), (3), (4), (6), (7), (10), and (13) in the modification of the first embodiment may be adopted.

### Fourth Embodiment

In the first to third embodiments described above, the consumption degree of the guide 67 is determined using the dummy substrate DW. The fourth embodiment is different from the first to third embodiments described above in that the consumption degree of the guide 67 is determined using the substrate W processed by the processing unit 31.

FIGS. 34A to 34C will be referred to. FIGS. 34A to 34C are side views of the hand of the fourth embodiment.

The initial position information P0 is acquired by clamping the substrate W by the newly replaced guide 67. The periodic position information P1 and P2 is preferably acquired at a predetermined cycle when the substrate W having the same diameter as the substrate W from which the initial position information P0 is acquired is transferred. The period during which the periodic position information P1 and P2 is acquired is preferably set to be long so that the periodic position information P1 and P2 can be acquired on the substrate having the same diameter.

FIGS. 35A and 35B will be referred to. FIG. 35A is a graph illustrating the relationship between the consumption degree of the guide provided in the indexer robot IR and the elapsed period, and FIG. 26B is a graph illustrating the relationship between the consumption degree of the guide provided in the center robot CR and the elapsed period.

The relationship between the consumption degree of the guide 67 and the guide 67A and the elapsed period is the same as that described in the first embodiment. In the fourth embodiment, in consideration of the configuration in which the consumption degree of the guide 67 is determined in the process of transferring the substrate W processed by the processing unit 31, the processing performed by the control unit CU in a case where the differential position information L exceeds the first threshold and the second threshold is different from that of the first embodiment.

That is, in a case where the differential position information L exceeds the first threshold (differential position information L1), the control unit CU issues a warning that the guide 67 of the pusher 87 and the two guides 67A on the distal end side should be replaced. This warning is the same as the first warning in a case where the first threshold is exceeded in the first embodiment. In a case where the differential position information L exceeds the second threshold (differential position information L2) after the differential position information L exceeds the first threshold, the control unit CU stops, for example, the process in which the indexer robot IR transfers the substrate W. Specifically, for example, the first hand 19 of the indexer robot IR opens the guide 67 from the substrate W, places the substrate W on the carrier C, and retracts from the carrier C.

As a result, in a case where the guide 67 and the guide 67A continue to be used beyond the differential position information L2 (second consumption degree), it is possible to prevent the substrate W from being damaged due to transfer failure of the substrate W.

The correspondence between the above-described fourth embodiment and the configuration of the present invention is as follows. The guide 67 of the pusher 87 corresponds to a “movable guide” in the present invention.

The present invention is not limited to the above embodiment, and can be modified as follows.
(1) In each of the first to fourth embodiments described above, the configuration of the substrate processing apparatus 1 has been described as an example, but the present invention is not limited to the substrate processing apparatus having such a configuration.
(2) In each of the first to fourth embodiments described above, the case of treating the circular substrate W and the dummy substrate DW has been described as an example, but the substrate W and the dummy substrate DW are not limited to a circular shape.

※ The present invention may be embodied in other specific
forms without departing from the spirit or essential
attributes thereof and, accordingly, reference should be
made to the appended claims, rather than to the foregoing
specification, as indicating the scope of the invention.

What is claimed is:

1. A substrate transfer apparatus that transfers a substrate, the apparatus comprising:
a hand that holds the substrate in a horizontal posture;
a horizontal drive mechanism that advances and retracts the hand in a horizontal plane in order to deliver the substrate;
at least two guides that are provided on the hand and clamp an outer peripheral surface of the substrate to separate and hold the substrate from the hand;
an advancing/retracting drive mechanism that drives at least one of the at least two guides to advance and retract with respect to the substrate as a movable guide;
an acquisition unit that acquires clamp position information indicating a position in the horizontal plane where the guide clamps the outer peripheral surface of the substrate; and
a control unit that determines a consumption degree of the guide on a basis of the acquired clamp position information.

2. The substrate transfer apparatus according to claim 1, wherein
the control unit is configured to:
calculate differential information between the clamp position information of the guide in an initial state and the acquired clamp position information of the guide; and
determine the consumption degree on a basis of the differential information.

3. The substrate transfer apparatus according to claim 2, wherein
the control unit performs first control in a case where the differential information exceeds a first threshold.

4. The substrate transfer apparatus according to claim 2, wherein
the control unit performs second control in a case where the differential information exceeds a second threshold having the consumption degree larger than the first threshold.

5. The substrate transfer apparatus according to claim 1, wherein
the advancing/retracting drive mechanism includes:
a motor that applies a driving force for the advancing/retracting drive; and
a sensor that detects rotation of the motor and outputs the rotation as a detection signal, and
the acquisition unit acquires the clamp position information on a basis of the detection signal given by the sensor.

6. The substrate transfer apparatus according to claim 1, wherein
the advancing/retracting drive mechanism includes a measurement unit that measures a movement distance of the guide and outputs the movement distance as a measurement signal, and
the acquisition unit acquires the clamp position information on a basis of the measurement signal given by the measurement unit.

7. The substrate transfer apparatus according to claim 1, wherein
the control unit causes an output unit that outputs information according to the consumption degree to output information according to the consumption degree.

8. The substrate transfer apparatus according to claim 1, wherein
the control unit stops transfer of the substrate according to the consumption degree.

9. The substrate transfer apparatus according to claim 1, wherein
the control unit operates the guide such that a contact position between the guide and the outer peripheral surface of the substrate changes according to the consumption degree.

10. A substrate processing apparatus, the apparatus comprising:
a substrate transfer apparatus that transfers a substrate; and
a processing unit that performs predetermined processing on the substrate transferred by the substrate transfer apparatus, wherein
the substrate transfer apparatus includes:
a hand that holds the substrate in a horizontal posture;
a horizontal drive mechanism that advances and retracts the hand in a horizontal plane in order to deliver the substrate;
at least two guides that are provided on the hand and clamp an outer peripheral surface of the substrate to separate and hold the substrate from the hand;
an advancing/retracting drive mechanism that drives at least one of the at least two guides to advance and retract with respect to the substrate as a movable guide;
an acquisition unit that acquires clamp position information indicating a position in the horizontal plane where the guide clamps the outer peripheral surface of the substrate; and
a control unit that determines a consumption degree of the guide on a basis of the acquired clamp position information.

11. The substrate processing apparatus according to claim 10, wherein
the substrate clamped by the guide when the clamp position information is acquired is a substrate to be processed by the processing unit.

12. The substrate processing apparatus according to claim 10, wherein
the substrate clamped by the guide when the clamp position information is acquired is a dummy substrate that is not processed by the processing unit.

13. The substrate processing apparatus according to claim 12, wherein
the dummy substrate is placed in the substrate processing apparatus in advance, and
the consumption degree is determined at a preset cycle.

14. The substrate processing apparatus according to claim 10, comprising:
a carrier placement part on which a carrier capable of housing a plurality of substrates is placed, wherein
the substrate transfer apparatus is a transfer robot that transfers a substrate placed in the carrier.

15. The substrate processing apparatus according to claim 10, comprising:
a carrier placement part on which a carrier capable of housing a plurality of substrates is placed; and
a temporary placement part on which a substrate transferred from the carrier is temporarily placed, wherein
the substrate transfer apparatus is a transfer robot that transfers the substrate placed in the temporary placement part to the processing unit.
